(19) United States
(12) Patent Application Publication
(10) Pub. No.: US 2026/0018113 A1
(43) Pub. Date: Jan. 15, 2026

(54) DISPLAY PANEL AND DISPLAY APPARATUS

(71) Applicant: Wuhan Tianma Microelectronics Co., Ltd., Wuhan (CN)

(72) Inventors: Shu ZHOU, Wuhan (CN); Dian ZHANG, Wuhan (CN)

(21) Appl. No.: 19/333,372

(22) Filed: Sep. 19, 2025

(30) Foreign Application Priority Data
Mar. 28, 2025 (CN) 202510387533.8

(51) Int. Cl. G09G 3/32; H10D 86/40; H10D 86/60

(52) U.S. Cl. CPC G09G 3/32; H10D 86/443; H10D 86/481; H10D 86/60; G09G 2300/0426; G09G 2300/043; G09G 2300/0842; G09G 2310/08

(57) ABSTRACT

Provided are a display panel and a display apparatus. The display panel includes: a light-transmitting hole; data lines, a part of which comprising a first routing; and gating units each comprising at least two gating switches, which have input terminals electrically connected to one source signal line, control terminals electrically connected to at least two control lines respectively, and output terminals electrically connected to at least two data lines respectively. The control lines comprise a first and a second control line. The gating units comprise a first and a second gating unit. For the first routings connected to the first and second gating units: those corresponding to a same first control line are arranged in different layers and overlap with each other; and those corresponding to the first and second control lines are arranged in different layers and at least partially do not overlap with each other.

### CROSS-REFERENCE TO RELATED APPLICATION

The present application claims priority to Chinese Patent Application No. 202510387533.8, filed on Mar. 28, 2025, the content of which is incorporated herein by reference in its entirety.

### TECHNICAL FIELD

The present disclosure relates to the field of display technologies, and in particular, to a display panel and a display apparatus.

### BACKGROUND

At present, in order to achieve a full screen, a hole-punching design may be performed on a display panel within a display region, and at least a part of signal lines are subjected to routing processing around a light-transmitting hole.

However, the existing routing design is difficult to simultaneously achieve narrowing a bezel and reducing signal interference between routings, thereby affecting the overall performance of the display panel.

### SUMMARY

Embodiments of the present disclosure provide a display panel and a display apparatus, which can optimize a routing design.

In a first aspect, an embodiment of the present disclosure provides a display panel, including:
a light-transmitting hole;
a first non-display region surrounding the light-transmitting hole;
a display region surrounding the first non-display region;
data lines, a part of the data lines including a first segment, a first routing and a second segment, where the first segment and the second segment are disconnected at two sides of the light-transmitting hole and at least located in the display region, and the first routing is connected between the first segment and the second segment and located in the first non-display region; and
a plurality of gating units, each gating unit including at least two gating switches, where in the gating unit, input terminals of the at least two gating switches are electrically connected to one source signal line, control terminals of the at least two gating switches are electrically connected to at least two control lines respectively, and output terminals of the at least two gating switches are electrically connected to at least two data lines respectively;
where the first routing corresponding to a control line is the first routing connected to a gating switch connected to the control line;
the at least two control lines include at least one first control line and at least one second control line; and
the plurality of gating units include a first gating unit and a second gating unit; and for the first routings connected to the first gating unit and the second gating unit: the first routings corresponding to a same first control line are arranged in different layers, and at least partially overlap with each other in a direction perpendicular to a plane of the display panel; and the first routings corresponding to the at least one first control line and the first routings corresponding to the at least one second control line are arranged in different layers, and the first routings corresponding to the at least one first control line at least partially do not overlap with the first routings corresponding to the at least one second control line in the direction perpendicular to the plane of the display panel.

In a second aspect, based on the same inventive concept, an embodiment of the present disclosure further provides a display apparatus including the above-mentioned display panel.

The technical solutions provided by the embodiments of the present disclosure have the following beneficial effects:

For the first routings connected to the first gating unit and the second gating unit, for the first routings corresponding to a same first control line, the writing of the data voltage onto this part of first routings is controlled by the same first control line, so that voltage jumps on this part of first routings occur simultaneously. There will be less mutual interference between such first routings. In the embodiments of the present disclosure, this part of first routings are arranged in different layers and at least partially overlap with each other, so that while this part of first routings do not generate greater interference, the wiring widths occupied by this part of first routings in the first non-display region is compressed, thereby effectively achieving the purpose of narrowing a bezel.

For the first routings connected to the first gating unit and the second gating unit, for the first routings corresponding to the first control line and the first routings corresponding to the second control line, since different control lines provide enable levels in a time-division manner, the voltages on the first routings corresponding to the first control line and the first routings corresponding to the second control line undergo time-division jumps. In the embodiments of the present disclosure, the first routings corresponding to the first control line and the first routings corresponding to the second control line are arranged in different layers and at least partially do not overlap with each other, so that the signal interference between the two parts of the first routings can be reduced through the staggered arrangement thereof.

The embodiments of the present disclosure provide a routing mode for data lines for a panel structure adopting a gating design. From the above-mentioned analysis, such a routing mode can enable the display panel to simultaneously achieve narrowing of a bezel and reducing the signal interference between the routings, so that the display panel can achieve better performance.

### BRIEF DESCRIPTION OF DRAWINGS

For the purpose of more clearly explaining the technical solutions in the embodiments of the present disclosure or in the prior art, the drawings required to be used for the description of the embodiments or the prior art will be briefly introduced below. Apparently, the drawings in the following description are some embodiments of the present disclosure, and those of skill in the art can obtain other drawings from these drawings without creative efforts.

FIG. 1 is a schematic structural diagram of a display panel provided by an embodiment of the present disclosure;

FIG. 2 is another schematic structural diagram of a display panel provided by an embodiment of the present disclosure;

FIG. 3 is still another schematic structural diagram of a display panel provided by an embodiment of the present disclosure;

FIG. 4 is yet another schematic structural diagram of a display panel provided by an embodiment of the present disclosure;

FIG. 5 is a cross-sectional view along a direction A1-A2 in FIG. 4;

FIG. 6 is yet another structural schematic diagram of a display panel provided by an embodiment of the present disclosure;

FIG. 7 is a schematic diagram of a film layer structure of a display panel provided by an embodiment of the present disclosure;

FIG. 8 is a schematic diagram of another film layer structure of a display panel provided by an embodiment of the present disclosure;

FIG. 9 is a schematic diagram of still another film layer structure of a display panel provided by an embodiment of the present disclosure;

FIG. 10 is a schematic diagram of yet another film layer structure of a display panel provided by an embodiment of the present disclosure;

FIG. 11 is a schematic diagram of a film layer position of a first routing provided by an embodiment of the present disclosure;

FIG. 12 is a schematic diagram of another film layer position of a first routing provided by an embodiment of the present disclosure;

FIG. 13 is a schematic diagram of still another film layer position of a first routing provided by an embodiment of the present disclosure;

FIG. 14 is a schematic diagram of yet another film layer position of a first routing provided by an embodiment of the present disclosure;

FIG. 15 is a schematic diagram of yet another film layer position of a first routing provided by an embodiment of the present disclosure;

FIG. 16 is a schematic diagram of yet another film layer position of a first routing provided by an embodiment of the present disclosure;

FIG. 17 is yet another structural schematic diagram of a display panel provided by an embodiment of the present disclosure;

FIG. 18 is a schematic diagram of yet another film layer position of a first routing provided by an embodiment of the present disclosure;

FIG. 19 is a schematic diagram of yet another film layer position of a first routing provided by an embodiment of the present disclosure;

FIG. 20 is yet another structural schematic diagram of a display panel provided by an embodiment of the present disclosure;

FIG. 21 is a schematic diagram of routings of scan lines and data lines in the related art;

FIG. 22 is yet another structural schematic diagram of a display panel provided by an embodiment of the present disclosure;

FIG. 23 is yet another structural schematic diagram of a display panel provided by an embodiment of the present disclosure;

FIG. 24 is yet another structural schematic diagram of a display panel provided by an embodiment of the present disclosure;

FIG. 25 is a schematic diagram of a film layer position of a first lead provided by an embodiment of the present disclosure;

FIG. 26 is a cross-sectional view along a direction B1-B2 in FIG. 23;

FIG. 27 is a structural schematic diagram of a pixel circuit provided by an embodiment of the present disclosure;

FIG. 28 is a schematic diagram of a film layer position of a second routing provided by an embodiment of the present disclosure;

FIG. 29 is a schematic diagram of another film layer position of a second routing provided by an embodiment of the present disclosure;

FIG. 30 is another structural schematic diagram of a pixel circuit provided by an embodiment of the present disclosure;

FIG. 31 is a schematic diagram of still another film layer position of a second routing provided by an embodiment of the present disclosure;

FIG. 32 is yet another structural schematic diagram of a display panel provided by an embodiment of the present disclosure;

FIG. 33 is a timing diagram provided by an embodiment of the present disclosure; and

FIG. 34 is a structural schematic diagram of a display apparatus provided by an embodiment of the present disclosure.

### DESCRIPTION OF EMBODIMENTS

In order to better understand technical solutions of the present disclosure, embodiments of the present disclosure are described in detail below in conjunction with the drawings.

It should be clear that the described embodiments are merely some rather than all of the embodiments of the present disclosure. All other embodiments acquired by those of ordinary skill in the art without creative efforts based on the described embodiments of the present disclosure shall fall within the protection scope of the present disclosure.

The terms used in the embodiments of the present disclosure are merely intended to describe specific embodiments, but not intended to limit the present disclosure. Singular forms of “a/an”, “said” and “the” used in the embodiments of the present disclosure and the appended claims are also intended to include plural forms, unless the context clearly indicates other otherwise.

It should be understood that the term “and/or” used herein is only used to describe the association relationship of associated objects, representing that there can be three relationships. For example, A and/or B can represent: A exists alone, A and B exist at the same time, and B exists alone. In addition, the character “/” herein generally represents that the associated objects before and after it are in an “or” relationship.

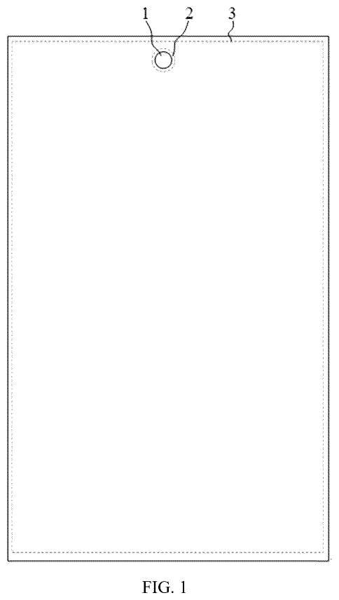

An embodiment of the present disclosure provides a display panel, as shown in FIG. 1, which is a structural schematic diagram of a display panel provided by an embodiment of the present disclosure, and the display panel includes a light-transmitting hole 1, a first non-display region 2, and a display region 3. An optical component such as a camera is correspondingly arranged at the light-transmitting hole 1; the first non-display region 2 surrounds the light-transmitting hole 1 and is a bezel region around the light-transmitting hole 1; and the display region 3 surrounds the first non-display region 2 and is a conventional display region.

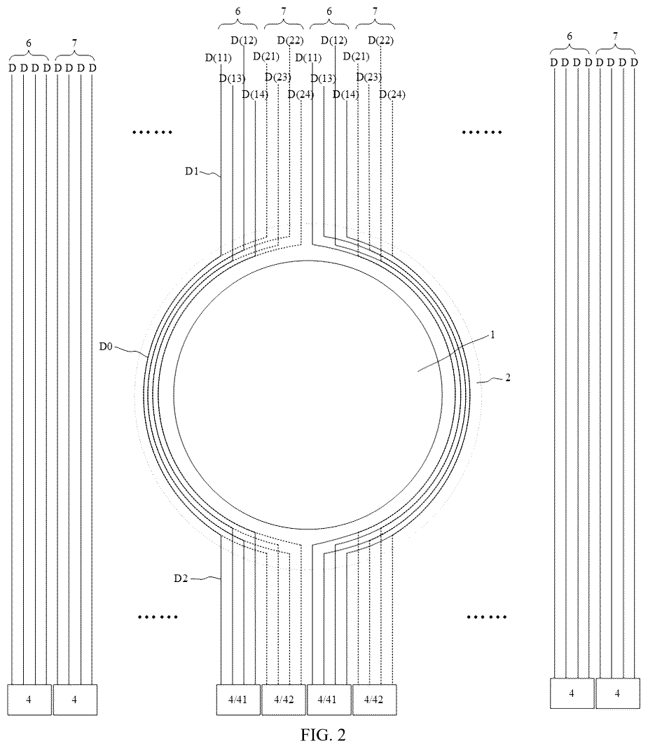

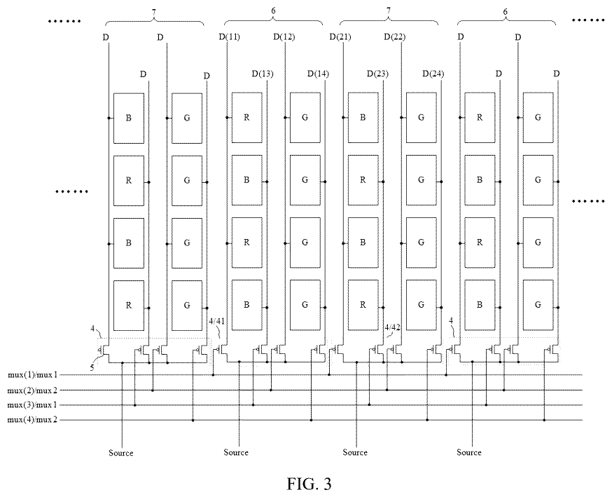

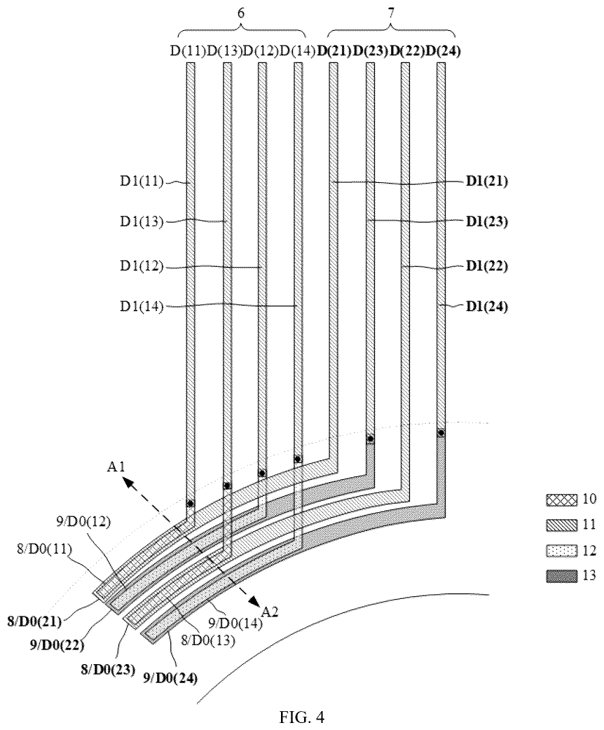

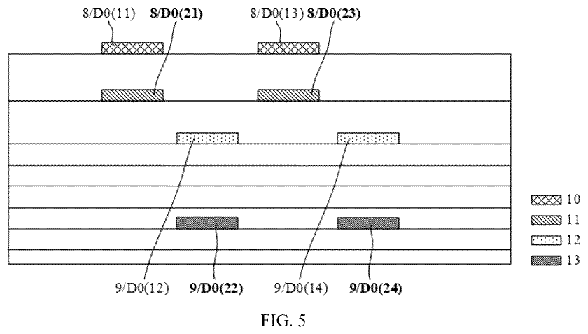

In conjunction with FIG. 1 to FIG. 5, FIG. 2 is another structural schematic diagram of a display panel provided by an embodiment of the present disclosure, FIG. 3 is still another structural schematic diagram of a display panel provided by an embodiment of the present disclosure, FIG. 4 is yet another structural schematic diagram of a display panel provided by an embodiment of the present disclosure, and FIG. 5 is a cross-sectional view along a direction A1-A2 in FIG. 4. The display panel further includes data lines D, and a part of the data lines D include a first segment D1, a first routing DO, and a second segment D2. The first segment D1 and the second segment D2 are disconnected at two sides of the light-transmitting hole 1 and at least located in the display region 3, and the first routing DO is connected between the first segment D1 and the second segment D2 and located in the first non-display region 2.

The display panel further includes a plurality of gating units 4, each gating unit 4 including at least two gating switches 5. In the gating unit 4, input terminals of the at least two gating switches 5 are electrically connected to one source signal line Source, control terminals of the at least two gating switches 5 are electrically connected to at least two control lines mux respectively, and output terminals of the at least two gating switches 5 are electrically connected to at least two data lines D respectively.

For ease of understanding, in the drawings of the embodiments of the present disclosure, the at least two control lines mux are respectively represented by reference signs mux (1) to mux (n), where n≥2.

For example, referring to FIG. 3, the gating unit 4 includes four gating switches 5. Correspondingly, the display panel includes four control lines, i.e., control lines mux (1) to mux (4). During a display driving process, the control lines mux (1) to mux (4) sequentially provide enable levels. When the control line mux (i) provides an enable level, the gating switches 5 connected to the control line mux (i) in the plurality of gating units 4 are turned on, and a data voltage on the source signal line Source is written into the data lines D connected to this part of gating switches 5.

The first routing DO corresponding to a control line mux is the first routing DO connected to the gating switch 5 connected to the control line mux.

That is, each control line mux is connected to a certain gating switch 5 in each of all gating units 4. This part of gating switches 5 connected to the control lines mux can be divided into two types: the data lines D connected to the first type of gating switches are conventional data lines, none of which includes the first routing DO, and the data lines D connected to the second type of gating switches each include the first routing DO. The first routings DO corresponding to a control line mux are then this part of first routings DO corresponding to the second type of gating switches connected to this control line mux.

The control lines mux include at least one first control line mux1 and at least one second control line mux2.

The gating units 4 include a first gating unit 41 and a second gating unit 42.

For the first routings DO respectively connected to the first gating unit 41 and the second gating unit 42, the first routings DO corresponding to a same first control line mux1 are arranged in different layers, and at least partially overlap with each other in a direction perpendicular to a plane of the display panel; and the first routings DO corresponding to the first control line mux1 and the first routings DO corresponding to the second control line mux2 are arranged in different layers, and the first routings DO corresponding to the first control line mux1 at least partially do not overlap with the first routings DO corresponding to the second control line mux2 in the direction perpendicular to the plane of the display panel.

For ease of understanding, in the drawings of the embodiments of the present disclosure, a data line connected to the first gating unit 41 and corresponding to the control line mux (i) is represented by a reference sign D(1i), and the first routing in the data line D(1i) is represented by a reference sign D0(1i); and a data line connected to the second gating unit 42 and corresponding to the control line mux (i) is represented by a reference sign D(2i), and the first routing in the data line D (2i) is represented by a reference sign D0(2i).

Taking FIG. 2 to FIG. 5 as an example, the first control line mux 1 includes a control line mux (1) and a control line mux (3), and the second control line mux2 includes a control line mux (2) and a control line mux (4).

Regarding “for the first routings DO connected to the first gating unit 41 and the second gating unit 42, the first routings DO corresponding to a same first control line mux1 are arranged in different layers, and at least partially overlap with each other”, exemplarily, in conjunction with FIG. 4 and FIG. 5, a first routing D0(11) and a first routing D0(21) corresponding to the control line mux (1) are arranged in different layers and at least partially overlap with each other; and a first routing D0(13) and a first routing D0(23) corresponding to the control line mux (3) are arranged in different layers and at least partially overlap with each other.

For the first routings DO connected to the first gating unit 41 and the second gating unit 42, for the first routings DO corresponding to a same first control line mux1, the writing of the data voltage onto this part of first routings DO is controlled by the same first control line mux1, so that voltage jumps on this part of first routings DO occur simultaneously. For example, the first routing D0(11) and the first routing D0(21) undergo voltage jumps simultaneously, and there will be less mutual interference between such first routings DO. In the embodiments of the present disclosure, this part of first routings DO are arranged in different layers and at least partially overlap with each other, so that while this part of first routings D0 do not generate greater interference, the wiring widths occupied by this part of first routings DO in the first non-display region 2 are compressed, thereby effectively achieving the purpose of narrowing a bezel.

Regarding “for the first routings DO connected to the first gating unit 41 and the second gating unit 42, the first routings DO corresponding to the first control line mux1 and the first routings DO corresponding to the second control line mux2 are arranged in different layers, and the first routings DO corresponding to the first control line mux1 at least partially do not overlap with the first routings DO corresponding to the second control line mux2”, exemplarily, in conjunction with FIG. 4 and FIG. 5, the first routing D0(11) and the first routing D0(21) corresponding to the control line mux (1) and a first routing D0(12) and a first routing D0(22) corresponding to the control line mux (2) are arranged in different layers, and the first routing D0(11) and the first routing D0(21) at least partially do not overlap with the first routing D0(12) and the first routing D0(22); and a first routing D0(13) and a first routing D0(23) corresponding to the control line mux (3) and a first routing D0(14) and a first routing D0(24) corresponding to the control line mux (4) are arranged in different layers, and the first routing D0(13) and the first routing D0(23) at least partially do not overlap with the first routing D0(14) and the first routing D0(24).

For the first routings DO connected to the first gating unit 41 and the second gating unit 42, for the first routings DO corresponding to the first control line mux1 and the first routings DO corresponding to the second control line mux2, since different control lines mux provide enable levels in a time-division manner, the voltages on the first routings DO corresponding to the first control line mux1 and the first routings DO corresponding to the second control line mux2 undergo time-division jumps. For example, after a data voltage is written into the first routing D0(11) and the first routing D0(21), they are in a floating state, and then the data voltage starts to be written into the first routing D0(12) and the first routing D0(22). In the embodiments of the present disclosure, the first routings DO corresponding to the first control line mux1 and the first routings DO corresponding to the second control line mux2 are arranged in different layers and at least partially do not overlap with each other, so that the signal interference between the two parts of the first routings DO can be reduced through the staggered arrangement thereof.

The embodiments of the present disclosure provide a routing mode for data lines for a panel structure adopting a gating design. As can be seen from the foregoing analysis, this routing mode can simultaneously achieve narrowing of a bezel and the reduction of signal interference between the routings, so that the display panel can achieve better performance.

In a feasible implementation, referring to FIG. 2 and FIG. 3, the display panel includes first data line groups 6 and second data line groups 7 that are alternately arranged, the first data line groups 6 and the second data line groups 7 respectively including at least two adjacent data lines D.

The first gating unit 41 is electrically connected to a first data line group 6, and the second gating unit 42 is electrically connected to a second data line group 7.

The fact that the first gating unit 41 and the second gating unit 42 are respectively connected to the first data line group 6 and the second data line group 7 means that the data lines D connected to the first gating unit 41 and the second gating unit 42 are adjacent to each other. Accordingly, when the first routings DO in this part of data lines D are subjected to the above-mentioned design, the overall wiring of the first routings DO will be relatively simple, which can reduce the wiring difficulty in the first non-display region 2.

In a feasible implementation, in conjunction with FIG. 2 to FIG. 5, the gating unit 4 includes 2m gating switches 5, and the control lines mux include m first control lines mux1 and m second control lines mux2, where m≥1. When m>1, the first control lines mux1 and the second control lines mux2 alternately provide enable levels. For example, when m=2, one first control line mux1, one second control line mux2, another first control line mux1 and another second control line mux2 sequentially provide enable levels.

The first routing DO includes a first sub-routing 8 corresponding to the first control line mux 1 and a second sub-routing 9 corresponding to the second control line mux2.

First sub-routings 8 electrically connected to the first gating unit 41 are located in a first metal layer 10, first sub-routings 8 electrically connected to the second gating unit 42 are located in a second metal layer 11, second sub-routings 9 electrically connected to the first gating unit 41 are located in a third metal layer 12, and second sub-routings 9 electrically connected to the second gating unit 42 are located in a fourth metal layer 13.

Moreover, for the first routings DO connected to a same gating unit 4, orthographic projections of two adjacent first sub-routings 8 on the plane of the display panel are spaced by an orthographic projection of one second sub-routing 9 on the plane of the display panel, and orthographic projections of two adjacent second sub-routings 9 on the plane of the display panel are spaced by an orthographic projection of one first sub-routing 8 on the plane of the display panel.

For example, the first control line mux1 includes the control line mux (1) and the control line mux (3), and the second control line mux2 includes the control line mux (2) and the control line mux (4).

The first sub-routings 8 include the first routing D0(11), the first routing D0(13), the first routing D0(21) and the first routing D0(23), and the second sub-routings 9 includes the first routing D0(12), the first routing D0(14), the first routing D0(22) and the first routing D0(24).

For the first routing D0(11), the first routing D0(12), the first routing D0(13) and the first routing D0(14) connected to the first gating unit 41, orthographic projections of two adjacent first routings D0(11) and D0(13) are spaced by an orthographic projection of the first routing D0(12) or an orthographic projection of the first routing D0(14); and orthographic projections of two adjacent first routings D0(12) and D0(14) are spaced by an orthographic projection of the first routing D0(11) or an orthographic projection of the first routing D0(13).

For the first routing D0(21), the first routing D0(22), the first routing D0(23), and the first routing D0(24) connected to the second gating unit 42, orthographic projections of two adjacent first routings D0(21) and D0(23) are spaced by an orthographic projection of the first routing D0(22) or an orthographic projection of the first routing D0(24); and orthographic projections of two adjacent first routings D0(22) and D0(24) are spaced by an orthographic projection of the first routing D0(21) or an orthographic projection of the first routing D0(23).

In the panel structure where one gating unit 4 drives 2m data lines, by adopting the above-mentioned design, on the premise of achieving narrowing a bezel and reducing the mutual interference between the first routings DO, the first routings DO only need to occupy four metal layers in total. The number of metal layers in the current panel film layer structure can meet the requirement that the first routings DO adopt four-layer wiring, and in turn there is no need to additionally add other metal layers in the panel film layer structure for the first routings DO.

Further, m=2, that is, when the gating unit 4 performs a 1-to-4 driving design for the data lines D.

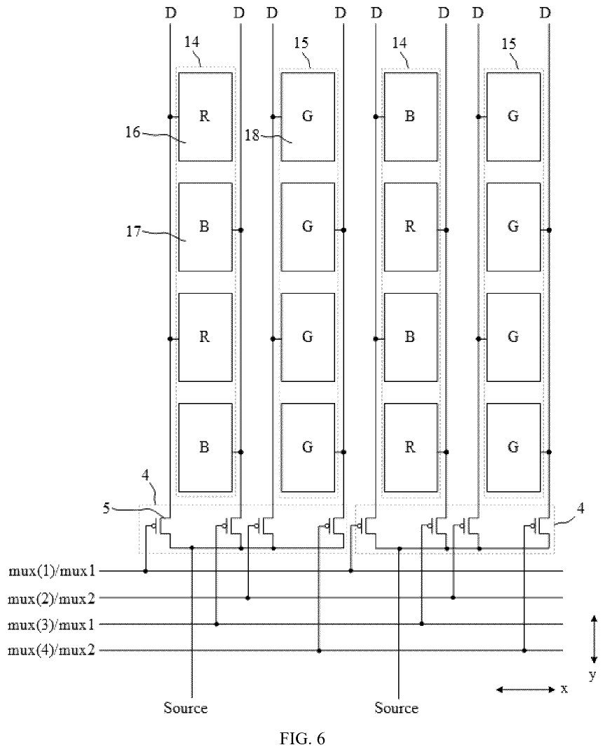

In one structure, as shown in FIG. 6, which is yet another structural schematic diagram of a display panel provided by an embodiment of the present disclosure, the display panel includes first circuit columns 14 and second circuit columns 15 that are alternately arranged in sequence along a first direction x. Each first circuit column 14 includes first pixel circuits 16 and second pixel circuits 17 that are alternately arranged along a second direction y, and each second circuit column 15 includes third pixel circuits 18 arranged along the second direction y. Moreover, in two adjacent first circuit columns 14, the first pixel circuits 16 in one first circuit column 14 and the second pixel circuits 17 in the other first circuit column 14 are arranged in alignment.

The first pixel circuits 16 are electrically connected to red light-emitting elements, the second pixel circuits 17 are electrically connected to blue light-emitting elements, and the third pixel circuits 18 are electrically connected to green light-emitting elements.

Each circuit column is electrically connected to two data lines D, one of which is electrically connected to the pixel circuits in the odd-numbered rows, and the other one of which is electrically connected to the pixel circuits in the even-numbered rows. The data lines D corresponding to two adjacent circuit columns are connected to one gating unit 4.

In this design, the number of data lines D is larger, and accordingly, the number of first routings DO is also larger. By adopting the above-mentioned design for the first routings D0, the bezel width occupied by the first routings DO in the first non-display region 2 can be reduced, and the signal interference between the first routings DO can also be reduced.

In subsequent embodiments, the optional film layer positions of the first routings DO will be described. For a clearer understanding of the solution, the present disclosure first introduces several film layer structures of the display panel.

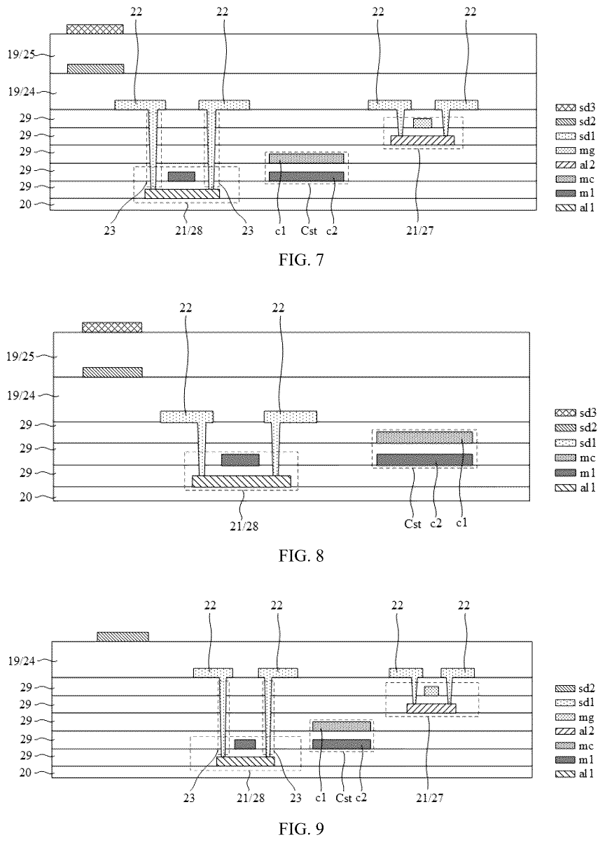

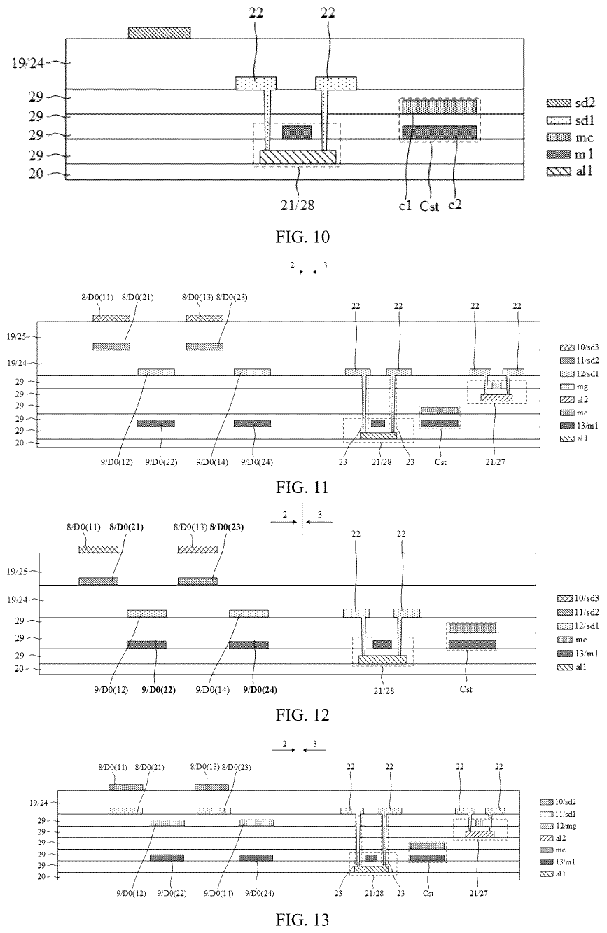

As shown in FIG. 7 to FIG. 10, FIG. 7 is a schematic diagram of a film layer structure of a display panel provided by an embodiment of the present disclosure, FIG. 8 is a schematic diagram of another film layer structure of a display panel provided by an embodiment of the present disclosure, FIG. 9 is a schematic diagram of still another film layer structure of a display panel provided by an embodiment of the present disclosure, and FIG. 10 is a schematic diagram of yet another film layer structure of a display panel provided by an embodiment of the present disclosure. The display panel further includes a substrate 20, a transistor 21, a storage capacitor Cst, and connection electrodes 22, where the connection electrodes 22 are electrically connected to a doped region of an active layer in the transistor 21 through via holes 23.

In a possible arrangement, referring to FIG. 7 and FIG. 8, the display panel includes three source-drain metal layers, i.e., a first source-drain metal layer sd1, a second source-drain metal layer sd2, and a third source-drain metal layer sd3, and such display panel is also referred to as having a “3SD structure”. The first source-drain metal layer sd1 includes the connection electrodes 22, the second source-drain metal layer sd2 is located on one side of the first source-drain metal layer sd1 away from the substrate 20, and the third source-drain metal layer sd3 is located on one side of the second source-drain metal layer sd2 away from the substrate 20. Moreover, the first source-drain metal layer sd1 and the second source-drain metal layer sd2 as well as the second source-drain metal layer sd2 and the third source-drain metal layer sd3 are spaced by planarization layers 19 respectively. The planarization layers 19 are generally organic film layers with a larger thickness.

In the “3SD structure”, the number of source-drain metal layers is larger, which is more suitable for the situation where the number of signal lines is larger and the number of metal layers required to be occupied is larger.

In another possible arrangement, referring to FIG. 9 and FIG. 10, the display panel only includes two source-drain metal layers, i.e., a first source-drain metal layer sd1 and a second source-drain metal layer sd2, and such display panel is also referred to as having a “2SD structure”. The first source-drain metal layer sd1 includes connection electrodes 22, and the second source-drain metal layer sd2 is located on one side of the first source-drain metal layer sd1 away from the substrate 20. Moreover, the first source-drain metal layer sd1 and the second source-drain metal layer sd2 are spaced by a planarization layer 19.

In the “2SD structure”, the number of source-drain metal layers is smaller, which is more suitable for the situation where the number of signal lines is smaller and the number of metal layers required to be occupied is not large.

In a possible arrangement, referring to FIG. 7 and FIG. 9, the transistor 21 includes a first transistor 27 and a second transistor 28. An active layer of the first transistor 27 includes a metal oxide semiconductor material, for example, the first transistor 27 is an indium gallium zinc oxide (IGZO) transistor; and an active layer of the second transistor 28 includes a silicon material, for example, the second transistor 28 is a low temperature poly Si (LTPS) transistor. Such display panel is also referred to as having a “LTPO structure”.

In this structure, the display panel further includes a first semiconductor layer al1, a first gate metal layer m1, a first electrode metal layer mc, a second semiconductor layer al2 and a second gate metal layer mg that are arranged in sequence along a direction away from the substrate 20.

The first semiconductor layer al1 includes the active layer of the second transistor 28; the first gate metal layer m1 includes a gate of the second transistor 28 and a second plate c2 of the storage capacitor Cst; the first electrode metal layer mc includes a first plate c1 of the storage capacitor Cst; the second semiconductor layer al2 includes the active layer of the first transistor 27; and the second gate metal layer mg includes a gate of the first transistor 27. The first source-drain metal layer sd1 is located on one side of the second gate metal layer mg away from the substrate 20. In the above-mentioned film layers, two adjacent film layers are respectively spaced by an inorganic insulating layer 29.

In another arrangement, referring to FIG. 8 and FIG. 10, the transistor 21 includes only one type of transistor, i.e., the second transistor 28, and such display panel is also referred to as having a “LTPS structure”.

In this structure, the display panel further includes a first semiconductor layer al1, a first gate metal layer m1, and a first electrode metal layer mc that are arranged in sequence along a direction away from the substrate 20.

The first semiconductor layer al1 includes an active layer of the second transistor 28; the first gate metal layer m1 includes a gate of the second transistor 28 and a second plate c2 of the storage capacitor Cst; and the first electrode metal layer mc includes a first plate c1 of the storage capacitor Cst. The first source-drain metal layer sd1 is located on one side of the first electrode metal layer mc away from the substrate 20. In the above-mentioned film layers, two adjacent film layers are respectively spaced by an inorganic insulating layer 29.

Then, optional film layer positions of the first routings DO are described below.

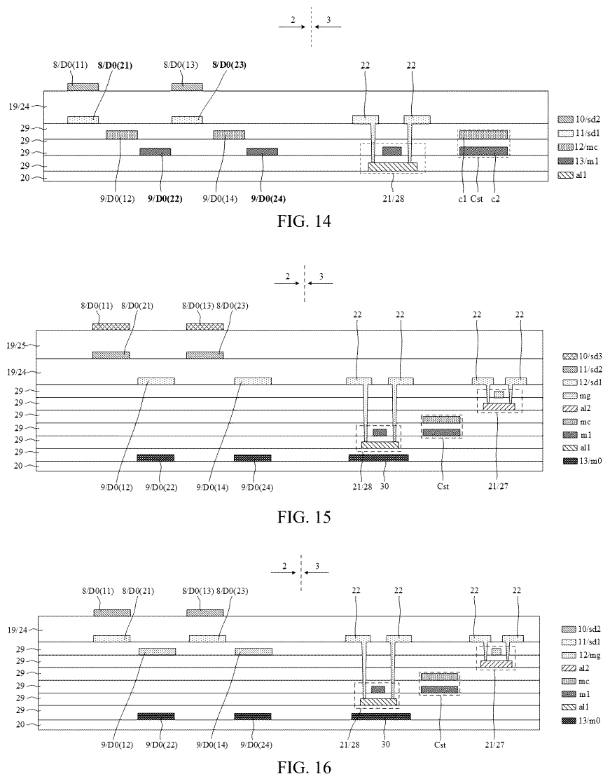

In a feasible implementation, as shown in FIG. 11 to FIG. 14, FIG. 11 is a schematic diagram of a film layer position of a first routing provided by an embodiment of the present disclosure, FIG. 12 is a schematic diagram of another film layer position of a first routing provided by an embodiment of the present disclosure, FIG. 13 is a schematic diagram of still another film layer position of a first routing provided by an embodiment of the present disclosure, and FIG. 14 is a schematic diagram of yet another film layer position of a first routing provided by an embodiment of the present disclosure. The first routing DO includes the first sub-routings 8 corresponding to the first control lines mux1.

The first sub-routings 8 electrically connected to the first gating unit 41 are located in a first metal layer 10, and the first sub-routings 8 electrically connected to the second gating unit 42 are located in a second metal layer 11. That is, a first routing D0(11) and a first routing D0(13) are located in the first metal layer 10, and a first routing D0(21) and a first routing D0(23) are located in the second metal layer 11. The first metal layer 10 and the second metal layer 11 are spaced by a planarization layer.

As can be seen in conjunction with the foregoing description, for the first sub-routings 8 corresponding to a same first control line mux1, the first sub-routing 8 connected to the first gating unit 41 overlaps with the first sub-routing 8 connected to the second gating unit 42. That is, the first routing D0(11) overlaps with the first routing D0(21), and the first routing D0(13) overlaps with the first routing D0(23).

By making the first metal layer 10 where the first sub-routings 8 connected to the first gating unit 41 are located and the second metal layer 11 where the first sub-routings 8 connected to the second gating unit 42 are located spaced by the planarization layer 19, a longitudinal distance between these two parts of first sub-routings 8 can be increased using the thicker planarization layer 19, thereby avoiding the generation of larger parasitic capacitance when the two overlap with each other, and further avoiding mutual influence between the two.

In addition, as can been seen in conjunction with the previous analysis of the film layer structure of the display panel, the fact that the first metal layer 10 and the second metal layer 11 are spaced by the planarization layer 19 means that at least one of the first metal layer 10 and the second metal layer 11 is a source-drain metal layer. For example, when the first metal layer 10 and the second metal layer 11 are spaced only by the planarization layer 19, both the first metal layer 10 and the second metal layer 11 are source-drain metal layers. Generally, due to the material resistance and other reasons of the source-drain metal layers, their impedance is lower. Therefore, when the first sub-routings 8 are located in the source-drain metal layers, they can also have smaller loads, which helps to balance the difference in load from the conventional data lines.

Further, referring to FIG. 11 and FIG. 12, the display panel further includes a substrate 20, a transistor 21 and connection electrodes 22. The connection electrodes 22 are electrically connected to a doped region of an active layer in the transistor 21 through via holes 23.

The planarization layer 19 includes a first planarization layer 24 and a second planarization layer 25. The first planarization layer 24 is located on one side of the connection electrodes 22 away from the substrate 20, and the second planarization layer 25 is located on one side of the first planarization layer 24 away from the substrate 20.

The first metal layer 10 is located on one side of the second planarization layer 25 away from the substrate 20, and the second metal layer 11 is located between the first planarization layer 24 and the second planarization layer 25.

Such an arrangement is more suitable for the “3SD structure”, in which the first metal layer 10 is the third source-drain metal layer sd3, and the second metal layer 11 is the second source-drain metal layer sd2. With this arrangement, the second planarization layer 25 can be used to reduce the parasitic capacitance between the overlapped first sub-routings 8, and the low impedance characteristic of the source-drain metal layers can also be used to reduce the loads of the first sub-routings 8.

In a feasible implementation, referring to FIG. 13 and FIG. 14, the display panel further includes a substrate 20, a transistor 21, and connection electrodes 22. The connection electrodes 22 are electrically connected to a doped region of an active layer in the transistor 21 through via holes 23.

The planarization layer 19 includes a first planarization layer 24 located on one side of the connection electrodes 22 away from the substrate 20.

The first metal layer 10 is located on one side of the first planarization layer 24 away from the substrate 20, and the second metal layer 11 includes the connection electrodes 22.

Such an arrangement is more suitable for the “2SD structure”, in which the first metal layer 10 is the second source-drain metal layer sd2, and the second metal layer 11 is the first source-drain metal layer sd1. With this arrangement, the first planarization layer 24 can be used to reduce the parasitic capacitance between the overlapped first sub-routings 8, and the lower impedance characteristic of the source-drain metal layers can also be used to reduce the load of the first sub-routings 8.

In a feasible implementation, referring to FIG. 11 to FIG. 14, the first routing DO includes the second sub-routings 9 corresponding to the second control line mux2.

The second sub-routings 9 electrically connected to the first gating unit 41 are located in a third metal layer 12, and the second sub-routings 9 electrically connected to the second gating unit 42 are located in a fourth metal layer 13. That is, the first routing D0(12) and the first routing D0(14) are located in the third metal layer 12, and the first routing D0(22) and the first routing D0(24) are located in the fourth metal layer 13. The third metal layer 12 and the fourth metal layer 13 are spaced by an inorganic insulating layer 29.

As can be seen in conjunction with the previous analysis of the film layer structure of the display panel, the fact that the third metal layer 12 and the fourth metal layer 13 are spaced by the inorganic insulating layer 29 means that at least one of the third metal layer 12 and the fourth metal layer 13 is a first source-drain metal layer sd1 or a metal layer below the first source-drain metal layer sd1.

For example, in the “3SD structure”, when the first sub-routings 8 are located in the topmost third source-drain metal layer sd3 and the second source-drain metal layer sd2, the second sub-routings 9 may be optionally located in the first source-drain metal layer sd1 or in metal layers below it such as the second gate metal layer mg, the first electrode metal layer mc, and the first gate metal layer m1. In the “2SD structure”, when the first sub-routings 8 are located in the topmost second source-drain metal layer sd2 and the first source-drain metal layer sd1, the second sub-routings 9 may be optionally located in metal layers below the first source-drain metal layer sd1, such as the second gate metal layer mg, the first electrode metal layer mc, and the first gate metal layer m1. Thereby, in the “3SD structure” and the “2SD structure”, film layer positions are reasonably configured for the first sub-routings 8 and the second sub-routings 9.

In a feasible implementation, referring to FIG. 11 to FIG. 13, there are other metal layers interposed between the third metal layer 12 and the fourth metal layer 13. For the second sub-routings 9 connected to the first gating unit 41 and the second gating unit 42, the second sub-routings 9 corresponding to a same second control line mux2 at least partially overlap with each other in a direction perpendicular to a plane of the substrate 20.

For example, referring to FIG. 11, the third metal layer 12 is the first source-drain metal layer sd1, the fourth metal layer 13 is the first gate metal layer m1, and the second gate metal layer mg and the first electrode metal layer mc are interposed between the third metal layer 12 and the fourth metal layer 13. The first routing D0(12) overlaps with the first routing D0(22), and the first routing D0(14) overlaps with the first routing D0(24).

As described above, for the first sub-routings 8 connected to the first gating unit 41 and the second gating unit 42, the first sub-routings 8 corresponding to a same first control line mux1 overlap with each other, to compress the bezel width occupied by the first sub-routings 8. In this embodiment, when other metal layers are interposed between the third metal layer 12 where the second sub-routings 9 connected to the first gating unit 41 are located and the fourth metal layer 13 where the second sub-routings 9 connected to the second gating unit 42 are located, it means that a longitudinal distance between the third metal layer 12 and the fourth metal layer 13 is larger, and in this regard, the second sub-routings 9 corresponding to a same second control line mux2 may also be arranged to overlap with each other, so that no larger parasitic capacitance is generated between this part of second sub-routings 9, and the bezel width occupied by the second sub-routings 9 is also compressed synchronously. For example, referring to FIG. 4, eight first routings DO connected to the first gating unit 41 and the second gating unit 42 occupy at least only four wiring widths, thereby narrowing the bezel to a greater extent.

It should be noted that the above-mentioned arrangement is more suitable for the “3SD structure” shown in FIG. 11 and FIG. 12 and the “2SD+LTPO structure” shown in FIG. 13. In these film layer structures, the number of metal layers is larger, which makes it easier to select two non-adjacent metals to arrange the second sub-routings 9.

When other metal layers are interposed between the third metal layer 12 and the fourth metal layer 13, in a feasible implementation, referring to FIG. 11 and FIG. 12, the display panel further includes a substrate 20, a transistor 21, and connection electrodes 22. The connection electrodes 22 are electrically connected to a doped region of an active layer in the transistor 21 through via holes 23.

The third metal layer 12 includes the connection electrodes 22, and the fourth metal layer 13 is located on one side of the third metal layer 12 close to the substrate 20.

Such an arrangement is more suitable for the “3SD structure”, in which the first metal layer 10 is the third source-drain metal layer sd3, the second metal layer 11 is the second source-drain metal layer sd2, the third metal layer 12 is the first source-drain metal layer sd1, and the fourth metal layer 13 is located on one side of the first source-drain metal layer sd1 close to the substrate 20.

The above-mentioned third metal layer 12 is the first source-drain metal layer sd1, so that on one hand, the lower-impedance characteristic of the source-drain metal layer can be used to reduce the loads of the second sub-routings 9 connected to the first gating unit 41, and on the other hand, the film layer position of the first source-drain metal layer sd1 is relatively upper, when selecting a metal layer which is not adjacent to the first source-drain metal layer sd1 as the fourth metal layer 13 below the first source-drain metal layer sd1, the position of the fourth metal layer 13 can be more flexibly chosen, and the longitudinal distance between the third metal layer 12 and the fourth metal layer 13 can also be increased to a greater extent, to reduce the parasitic capacitance between the second sub-routing 9 connected to the first gating unit 41 and the second sub-routing 9 connected to the second gating unit 42 that overlap with each other to a greater extent, thereby reducing the mutual signal interference therebetween.

When other metal layers are interposed between the third metal layer 12 and the fourth metal layer 13, in another feasible implementation, referring to FIG. 13, the display panel further includes a substrate 20 and a transistor 21. The transistor 21 includes a first transistor 27, and an active layer of the first transistor 27 includes a metal oxide material.

The third metal layer 12 includes a gate of the first transistor 27, and the fourth metal layer 13 is located on one side of the third metal layer 12 close to the substrate 20.

Such an arrangement is more suitable for the “2SD structure+LTPO structure”, in which the first metal layer 10 is the second source-drain metal layer sd2, the second metal layer 11 is the first source-drain metal layer sd1, the third metal layer 12 is the second gate metal layer mg, and the fourth metal layer 13 is located on one side of the second gate metal layer mg close to the substrate 20.

The above-mentioned third metal layer 12 is the second gate metal layer mg. The film layer position of the second gate metal layer mg is relatively upper, when selecting a metal layer which is not adjacent to the second gate metal layer mg as the fourth metal layer 13 below the second gate metal layer mg, the position of the fourth metal layer 13 can be more flexibly chosen, and the longitudinal distance between the third metal layer 12 and the fourth metal layer 13 can be increased to a greater extent, to reduce the parasitic capacitance between the second sub-routing 9 connected to the first gating unit 41 and the second sub-routing 9 connected to the second gating unit 42 that overlap with each other to a greater extent.

In a feasible implementation, referring to FIG. 11 to FIG. 13, the transistor 21 includes a second transistor 28, an active layer of the second transistor 28 includes a silicon material, and the fourth metal layer 13 includes a gate of the second transistor 28. That is, the fourth metal layer 13 is the first gate metal layer m1.

For example, in the “3SD structure” shown in FIG. 11 and FIG. 12, the third metal layer 12 is the first source-drain metal layer sd1, and the fourth metal layer 13 is the first gate metal layer m1. Or, in the “2SD structure+LTPO structure” shown in FIG. 13, the third metal layer 12 is the second gate metal layer mg, and the fourth metal layer 13 is the first gate metal layer m1.

Or, as shown in FIG. 15 and FIG. 16, FIG. 15 is a schematic diagram of yet another film layer position of a first routing provided by an embodiment of the present disclosure, and FIG. 16 is a schematic diagram of yet another film layer position of a first routing provided by an embodiment of the present disclosure. The display panel further includes a shielding metal 30 located between the transistor 21 and the substrate 20. In the direction perpendicular to the plane of the substrate 20, the shielding metal 30 overlaps with a channel of the transistor 21. The fourth metal layer 13 includes the shielding metal 30.

In this structure, the display panel further includes a shielding metal layer m0 located between the first semiconductor layer al1 and the substrate 20. The shielding metal layer m0 and the first semiconductor layer al1 are spaced by an inorganic insulating layer 29, and the fourth metal layer 13 is the shielding metal layer m0. For example, in the “3SD structure” shown in FIG. 15, the third metal layer 12 is the first source-drain metal layer sd1, and the fourth metal layer 13 is the shielding metal layer m0. Or, in the “2SD structure+LTPO structure” shown in FIG. 16, the third metal layer 12 is the second gate metal layer mg, and the fourth metal layer 13 is the shielding metal layer m0.

In the film layer structure of the display panel, positions of the first gate metal layer m1 and the shielding metal layer m0 are both closer to the substrate 20. When the fourth metal layer 13 is the first gate metal layer m1 or the shielding metal layer m0, a longitudinal distance between the fourth metal layer 13 and the third metal layer 12 is larger, the parasitic capacitance between the second sub-routing 9 connected to the first gating unit 41 and the second sub-routing 9 connected to the second gating unit 42 is smaller, and the signal influence between the two is smaller.

In a feasible implementation, further referring to FIG. 14, the third metal layer 12 and the fourth metal layer 13 are two adjacent metal layers. For the second sub-routings 9 connected to the first gating unit 41 and the second gating unit 42, the second sub-routings 9 corresponding to a same second control line mux2 at least partially do not overlap with each other in the direction perpendicular to the plane of the substrate 20.

For example, referring to FIG. 14, the third metal layer 12 is the first electrode metal layer mc, the fourth metal layer 13 is the first gate metal layer m1, and the third metal layer 12 and the fourth metal layer 13 are adjacent to each other without other metal layer interposed between the two. The first routing D0(12) at least partially does not overlap with the first routing D0(22), and the first routing D0(14) at least partially does not overlap with the first routing D0(24).

When the third metal layer 12 where the second sub-routings 9 connected to the first gating unit 41 are located and the fourth metal layer 13 where the second sub-routings 9 connected to the second gating unit 42 are located are adjacent metal layers, it means that a longitudinal distance between the third metal layer 12 and the fourth metal layer 13 is smaller, and in this regard, for the second sub-routings 9 connected to the first gating unit 41 and the second gating unit 42, the second sub-routings 9 corresponding to a same second control line mux2 can be optionally arranged to be at least partially not-overlapping with each other, so that they are staggered from each other, thereby reducing the parasitic capacitance between this part of second sub-routings 9 and reducing the mutual signal interference between the two.

It should be noted that the above-mentioned arrangement is more suitable for the “2SD+LTPS structure” shown in FIG. 14. In this film layer structure, the number of metal layers is smaller, so that two adjacent metals can be selected to arrange the second sub-routings 9.

When the third metal layer 12 and the fourth metal layer 13 are two adjacent metal layers, in a feasible implementation, further referring to FIG. 14, the display panel further includes a substrate 20, a storage capacitor Cst, and a transistor 21. The transistor 21 includes a second transistor 28, and an active layer of the second transistor 28 includes a silicon material.

The third metal layer 12 includes a first plate c1 of the storage capacitor Cst, and the fourth metal layer 13 includes a gate of the second transistor 28 and a second plate c2 of the storage capacitor Cst.

The first metal layer 10 is the second source-drain metal layer sd2, the second metal layer 11 is the first source-drain metal layer sd1, the third metal layer 12 is the first electrode metal layer mc, and the fourth metal layer 13 is the first gate metal layer m1. Therefore, in the “2SD structure+LTPS structure”, reasonable film layer positions are configured for the four metal layers where the first sub-routings 8 and the second sub-routings 9 are located, the parasitic capacitance between the second sub-routing 9 connected to the first gating unit 41 and the second sub-routing 9 connected to the second gating unit 42 is reduced, and the mutual signal influence between the two is reduced.

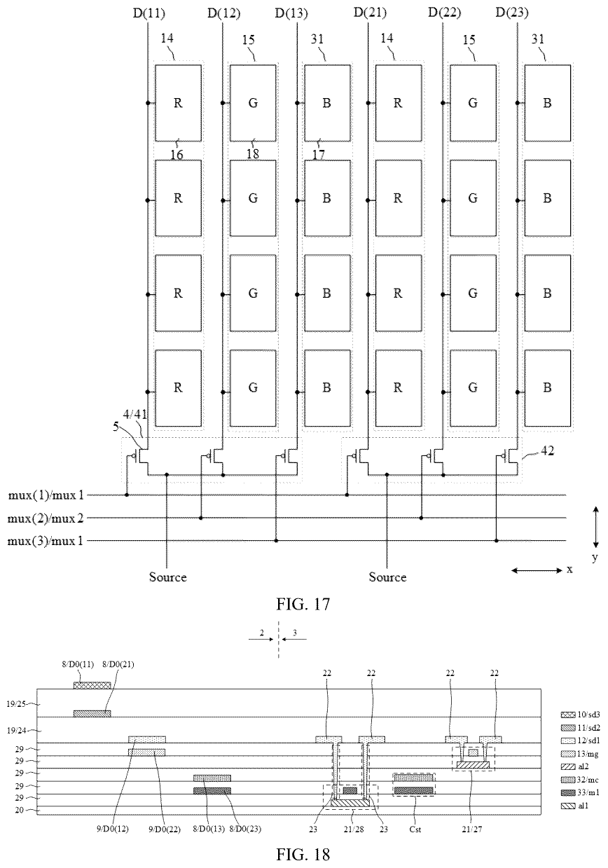

In a feasible implementation, as shown in FIG. 17 and FIG. 18, FIG. 17 is yet another structural schematic diagram of a display panel provided by an embodiment of the present disclosure, and FIG. 18 is a schematic diagram of yet another film layer position of a first routing DO provided by an embodiment of the present disclosure. The gating unit 4 includes three gating switches 5, and the control lines mux include n first control lines mux1 and 3-n second control lines mux2, where n=1 or n=2.

More specifically, in one structure, referring to FIG. 17, the display panel includes a first circuit column 14, a second circuit column 15, and a third circuit column 31 that are alternately arranged in sequence along the first direction x. The first circuit column 14 includes a plurality of first pixel circuits 16 arranged along the second direction y, the second circuit column 15 includes a plurality of third pixel circuits 18 arranged along the second direction y, and the third circuit column 31 includes a plurality of second pixel circuits 17 arranged along the second direction y.

One circuit column is connected to one data line D. Data lines D corresponding to three adjacent circuit columns are connected to one gating unit 4.

For the first routings DO corresponding to the first control line mux, the first routings DO electrically connected to the first gating unit 41 and the second gating unit 42 are respectively located in the first metal layer 10 and the second metal layer 11. That is, the first routing D0(11) corresponding to the control line mux (1) and connected to the first gating unit 41 is located in the first metal layer 10, and the first routing D0(21) corresponding to the control line mux (1) and connected to the second gating unit 42 is located in the second metal layer 11.

For the first routings DO corresponding to the second control line mux, the first routings DO electrically connected to the first gating unit 41 and the second gating unit 42 are respectively located in the third metal layer 12 and the fourth metal layer 13. That is, the first routing D0(12) corresponding to the control line mux (2) and connected to the first gating unit 41 is located in the third metal layer 12, and the first routing D0(22) corresponding to the control line mux (2) and connected to the second gating unit 42 is located in the fourth metal layer 13.

For the first routings DO corresponding to the third control line mux, the first routings DO electrically connected to the first gating unit 41 and the second gating unit 42 are respectively located in the fifth metal layer 32 and the sixth metal layer 33. That is, the first routing D0(13) corresponding to the control line mux (3) and connected to the first gating unit 41 is located in the fifth metal layer 32, and the first routing D0(23) corresponding to the control line mux (3) and connected to the second gating unit 42 is located in the sixth metal layer 33.

Such a structure may be more suitable for the “3SD structure”. In the “3SD structure”, the number of the metal layers is larger, which can meet the requirement that the first routings DO adopt six-layer wiring. The first routings DO only need to be located in the original metal layers, without additionally adding other metal layers for the first routings DO. For example, the first metal layer 10 is the third source-drain metal layer sd3, the second metal layer 11 is the second source-drain metal layer sd2, the third metal layer 12 is the first source-drain metal layer sd1, the fourth metal layer 13 is the second gate metal layer mg, the fifth metal layer 32 is the first electrode metal layer mc, and the sixth metal layer 33 is the first gate metal layer m1.

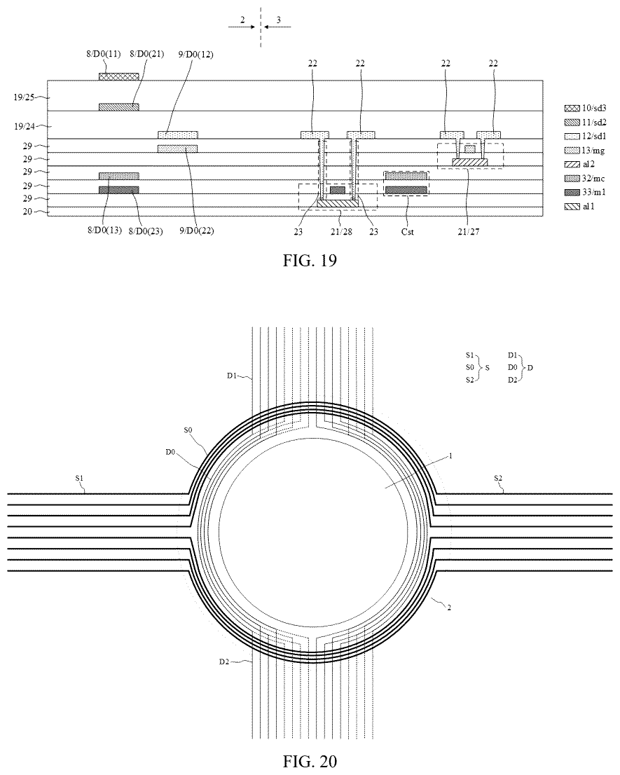

Further, as shown in FIG. 19, which is a schematic diagram of yet another film layer position of a first routing provided by an embodiment of the present disclosure, n=2, that is, two of three control lines mux are the first control lines mux1, and one of three control lines mux is the second control line mux2. The second control line mux2 provides an enable level between the two first control lines mux1.

The display panel further includes a substrate 20, and distances between the first metal layer 10, the second metal layer 11, the third metal layer 12, the fourth metal layer 13, the fifth metal layer 32, and the sixth metal layer 33 and the substrate 20 decrease gradually.

For the first routings DO electrically connected to the first gating unit 41 and the second gating unit 42, the first routings DO corresponding to one of the first control lines mux 1 are respectively located in the first metal layer 10 and the second metal layer 11, and the first routings DO corresponding to the other one of the first control lines mux1 are respectively located in the fifth metal layer 32 and the sixth metal layer 33. Moreover, the first routings DO corresponding to the two first control lines mux1 at least partially overlap with each other in the direction perpendicular to the plane of the display panel. That is, the first routing D0(11), the first routing D0(21), the first routing D0(13) and the first routing D0(23) overlap with each other.

By arranging the first routings DO corresponding to the two first control lines mux 1 to overlap with each other, the six routings corresponding to the first gating unit 41 and the second gating unit 42 occupy at least only two wiring widths, which can further narrow the bezel.

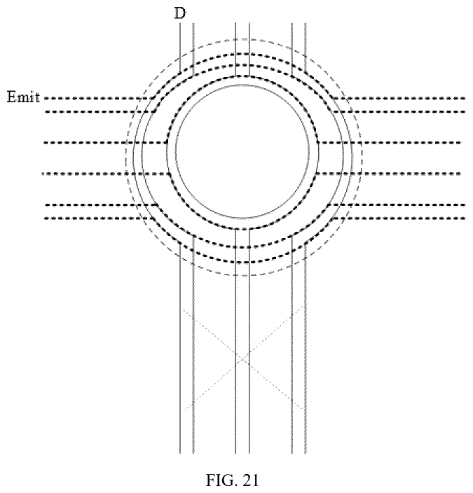

In a feasible implementation, as shown in FIG. 20, which is yet another structural schematic diagram of a display panel provided by an embodiment of the present disclosure, the display panel further includes first scan lines S, a part of the first scan lines S each including a third segment S1, a second routing S0 and a fourth segment S2. The third segment S1 and the fourth segment S2 are disconnected at two sides of the light-transmitting hole 1 and at least located in the display region 3, and an extension direction of the third segment S1 and the fourth segment S2 intersects with an extension direction of the first segment D1 and the second segment D2; and the second routing S0 is connected between the third segment S1 and the fourth segment S2 and located in the first non-display region 2.

In the embodiments of the present disclosure, the second routing S0 is located on one side of the first routing DO away from the light-transmitting hole 1.

In the related art, when arranging the routings of the scan lines and the routings of the data lines, the two types of routings overlap with each other. However, the inventor has found that under this design, the coupling between the two types of routings is large, which can easily lead to adverse problems such as XX mura and heavy-load screen splitting.

For example, as shown in FIG. 21, which is a schematic diagram of routings of scan lines and data lines in the related art, taking the scan lines including light-emitting control scan lines Emit as an example, the routings of the innermost data lines D have the largest amount of overlap with the routings of the light-emitting control scan lines Emit. When light-emitting control scan signals jump, the voltage on the routings of this part of data lines D is affected, to form a point (bright or dark point); and the routings of the outermost data lines D have the smallest amount of overlap with the routings of the light-emitting control scan lines Emit, two light-emitting control scan lines Emit overlapping with the routings of the outermost data lines D are farther apart, and when light-emitting control scan signals jump, two farthest points (bright or dark point) are formed, thereby resulting in the XX mura phenomenon.

In contrast, in the embodiments of the present disclosure, referring to FIG. 20, the second routing S0 of the first scan line S is located on the one side of the first routing DO away from the light-transmitting hole 1, and the two types of routings are arranged separately, so that the jump of the scan signal has less interference on the data signal on the routing, thereby effectively improving poor display problems such as XX mura and heavy-load screen splitting.

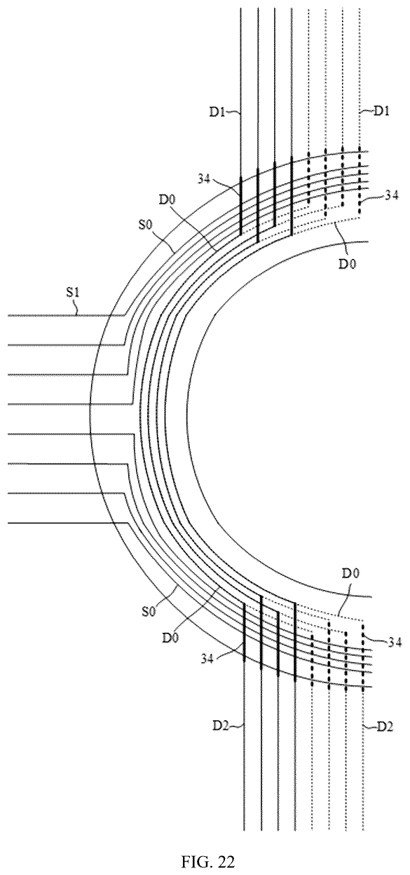

In a feasible implementation, as shown in FIG. 22, which is yet another structural schematic diagram of a display panel provided by an embodiment of the present disclosure, the first routing DO and the first segment D1 as well as the first routing DO and the second segment D2 are connected via first leads 34 respectively.

In the direction perpendicular to the plane of the display panel, the first leads 34 overlap with the second routing S0, and the first leads 34 extend in a same direction as the first segment D1 and the second segment D2.

The first leads 34 directly cross the second routing S0 longitudinally to be connected to the first routing DO. An extension distance of the first leads 34 is shorter, so that the coupling between the first leads 34 and the second routing S0 is smaller, which can further reduce the interference of the jump of the scan signal on the data signal.

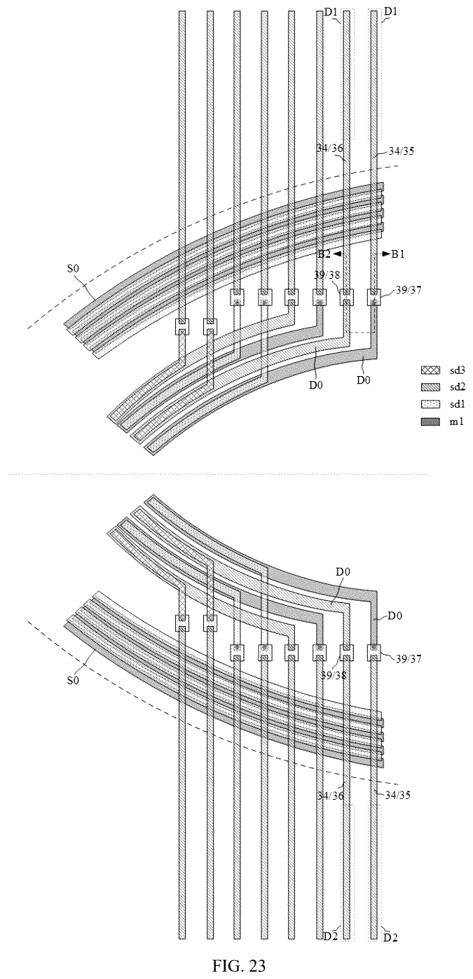

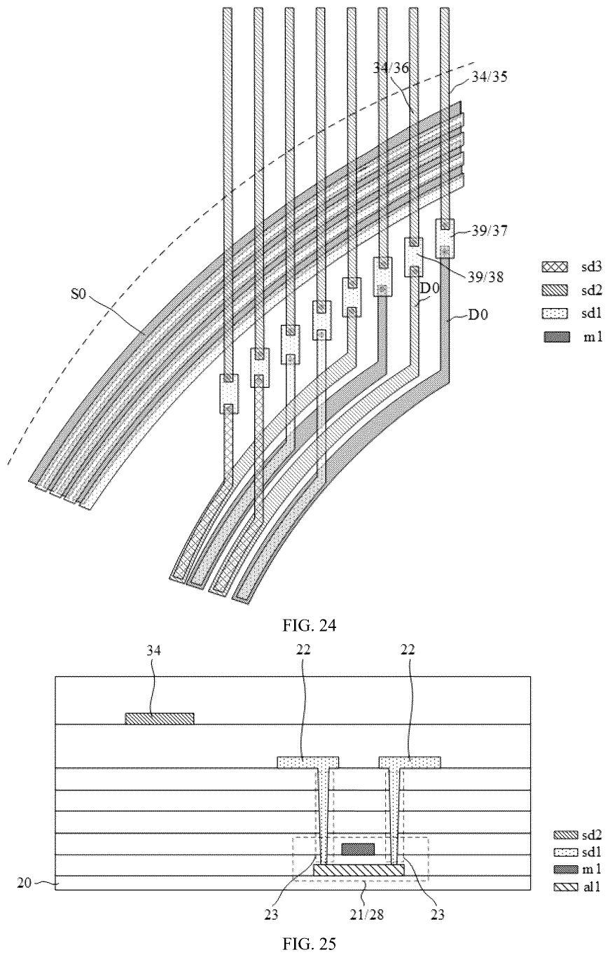

In a feasible implementation, as shown in FIG. 23 and FIG. 24, FIG. 23 is yet another structural schematic diagram of a display panel provided by an embodiment of the present disclosure, and FIG. 24 is yet another structural schematic diagram of a display panel provided by an embodiment of the present disclosure. The first leads 34 are arranged in a same layer as the first segment D1 and the second segment D2, so that there is no need to punch holes to connect the first leads 34 with the first segment D1 and the second segment D2 respectively.

And/or, as shown in FIG. 25, which is a schematic diagram of a film layer position of a first lead provided by an embodiment of the present disclosure, the display panel further includes a substrate 20, a transistor 21 and connection electrodes 22. The connection electrodes 22 are electrically connected to a doped region of an active layer in the transistor 21 through via holes 23. A metal layer where the first lead 34 is located is arranged on one side of a metal layer where the connection electrodes 22 are located away from the substrate 20. That is, the first lead 34 is located in the second source-drain metal layer sd2 or the third source-drain metal layer sd3. As such, the lower impedance characteristic of the source-drain metal layer can be used to reduce the load of the first lead 34, thereby weakening the load difference between the data lines D with routing and the conventional data lines D.

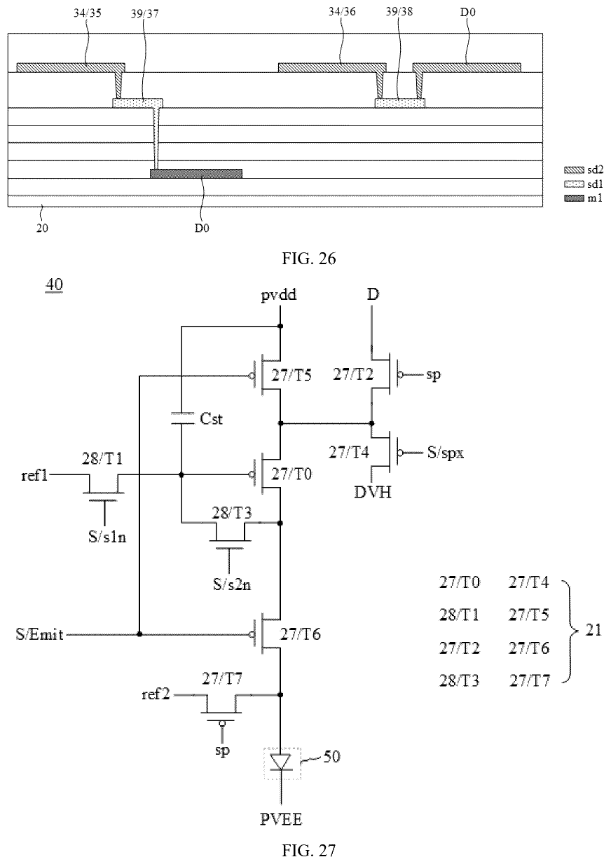

In a feasible implementation, in conjunction with FIG. 23 and FIG. 26, FIG. 26 is a cross-sectional view along a direction B1-B2 in FIG. 23, and the first leads 34 includes a first sub-lead 35 and a second sub-lead 36.

The first sub-lead 35 and the first routing DO connected thereto are arranged in different layers and connected to each other through a first connection portion 37, and the second sub-lead 36 and the first routing DO connected thereto are arranged in a same layer and connected to each other through a second connection portion 38. The first connection portion 37 and the second connection portion 38 are arranged in a same layer, for example, can be located in the second source-drain metal layer sd2. Further, the first connection portion 37 and the second connection portion 38 are arranged in different layers from the second sub-lead 36.

There are a plurality of possibilities for the film layer position of the first routing DO. Therefore, when the first sub-lead 35 and the first routing DO connected thereto are arranged in different layers, no matter which layer the first routing DO is located in, the first sub-lead 35 and the first routing DO can be connected to each other for line switching through the first connection portion 37 located in a same layer, to simplify the punching design. At the same time, when the first sub-lead 35 and the first routing DO connected thereto are arranged in a same layer, in order to improve the distribution uniformity of connection portions in the first non-display region 2, the first sub-lead 35 and the first routing DO can also be connected to each other for line switching through the second connection portion 38 in the same layer as the first connection portion 37.

In a feasible implementation, further referring to FIG. 23, at least some first leads 34 and first routings DO connected thereto are arranged in different layers and are connected to each other through connection portions 39, and the connection portions 39 are located between the first routings DO and second routings S0.

The connection portions 39 do not overlap with the second routings S0, and thus the ends of the first routings DO do not need to overlap with the second routings S0. The film layer positions of the first routings DO and the second routings S0 do not affect each other. Even if a part of the first routings DO and the second routings S0 are in a same layer, they may be not short-circuited, thereby maximizing the utilization of traces in the film layer.

In a feasible implementation, referring to FIG. 27 to FIG. 29, the display panel includes at least two types of first scan lines S, and different types of first scan lines S are used to provide different types of scan signals. For example, one type of first scan lines S is used to provide gate reset scan signals, and another type of first scan lines S is used to provide light-emitting control scan signals.

Second routings S0 of a same type of first scan lines S are arranged in a same layer, second routings S0 of different types of first scan lines are arranged in different layers, and in the direction perpendicular to the plane of the display panel, there is at least an overlap between second routings S0 of two types of first scan lines S.

Such an arrangement can compress the wiring widths required to be occupied by the second routings S0 in the first non-display region 2, which helps to further narrow the bezel.

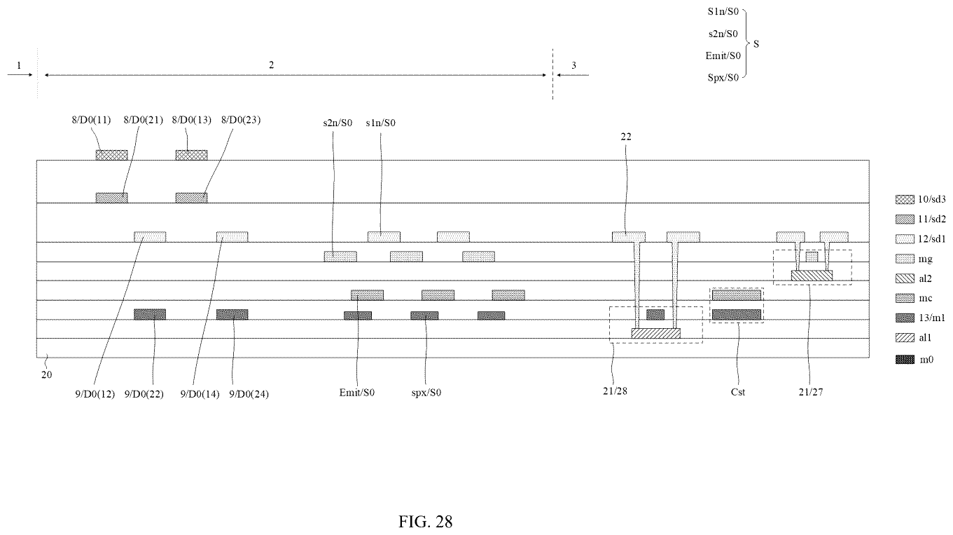

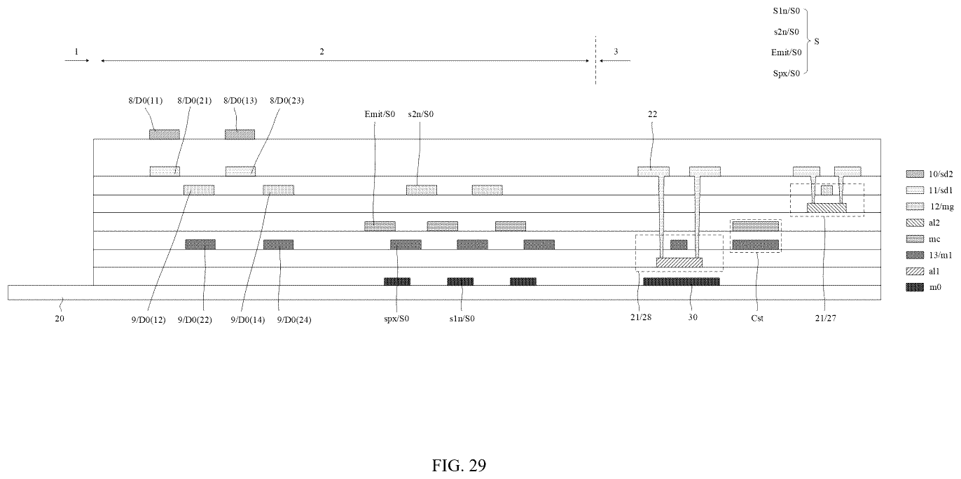

In a feasible implementation, as shown in FIG. 27 to FIG. 29, FIG. 27 is a structural schematic diagram of a pixel circuit provided by an embodiment of the present disclosure, FIG. 28 is a schematic diagram of a film layer position of a second routing provided by an embodiment of the present disclosure, and FIG. 29 is a schematic diagram of another film layer position of a second routing provided by an embodiment of the present disclosure. The display panel includes a pixel circuit 40, and the pixel circuit 40 includes a storage capacitor Cst and a plurality of transistors 21. The transistors 21 include a first transistor 27 and a second transistor 28, an active layer of the first transistor 27 includes a metal oxide material, and an active layer of the second transistor 28 includes a silicon material.

The display panel further includes connection electrodes 22 electrically connected to a doped region of the active layer in each transistor 21 through via holes 23, and second routings S0 of one type of first scan lines S are arranged in a same layer as the connection electrodes 22. That is, the second routings S0 of these first scan lines S are located in the first source-drain metal layer sd1.

And/or, second routings S0 of another type of first scan lines S and a gate of the first transistor 27 are arranged in a same layer. That is, the second routings S0 of these first scan lines S are located in the second gate metal layer mg.

And/or, second routings S0 of still another type of first scan lines S and a first plate c1 of the storage capacitor Cst are arranged in a same layer. That is, the second routings S0 of the first scan lines S are located in the first electrode metal layer mc.

And/or, second routings S0 of yet another type of first scan lines S are arranged in a same layer as a gate of the second transistor 28 and a second plate c2 of the storage capacitor Cst. That is, the second routings S0 of these first scan lines S are located in the first gate metal layer m1.

And/or, the display panel further includes a shielding metal 30 located between the second transistor 28 and the substrate 20. The shielding metal 30 overlaps with a channel of the second transistor 28 in a direction perpendicular to a plane of the substrate 20, and second routings S0 of a further type of first scan lines S are arranged in a same layer as the shielding metal 30. That is, the second routings S0 of these first scan lines S are located in the shielding metal layer m0.

Such an arrangement is applied to a panel having the “LTPO structure”. In such a display panel, the number of metal layers is larger, and thus more optional film layer positions can be provided for the second routings S0 of multiple types of first scan lines S, to achieve the reasonable arrangement of the second routings S0.

In a feasible implementation, referring to FIG. 27 to FIG. 29, the plurality of transistors 21 include a driving transistor T0, a gate reset transistor T1, a data writing transistor T2, a threshold compensation transistor T3, a bias transistor T4, a first light-emitting control transistor T5, a second light-emitting control transistor T6, and an anode reset transistor T7.

The gate reset transistor T1 is electrically connected to a gate reset scan line s1n, a gate reset line ref1 and a gate of the driving transistor T0 respectively.

The data writing transistor T2 is electrically connected to a data writing scan line sp, one data line D and a first electrode of the driving transistor T0 respectively.

The threshold compensation transistor T3 is electrically connected to a compensation scan line s2n, a second electrode of the driving transistor T0 and the gate of the driving transistor T0 respectively.

The bias transistor T4 is electrically connected to a bias scan line spx, a bias signal line DVH and the driving transistor T0 respectively. Exemplarily, the bias transistor T4 is electrically connected to the first electrode of the driving transistor T0.

The first light-emitting control transistor T5 is electrically connected to a light-emitting control scan line Emit, a power line pvdd and the first electrode of the driving transistor T0 respectively.

The second light-emitting control transistor T6 is electrically connected to the light-emitting control scan line Emit, the second electrode of the driving transistor T0 and a light-emitting element 50 respectively.

The anode reset transistor T7 is electrically connected to the data writing scan line sp, an anode reset line ref2, and the light-emitting element 50 respectively; or, the anode reset transistor T7 is electrically connected to the bias scan line spx, the anode reset line ref2 and the light-emitting element 50 respectively.

The first transistor 27 includes at least one of the gate reset transistor T1 and the threshold compensation transistor T3, and the second transistor 28 includes at least one of the driving transistor T0, the data writing transistor T2, the first light-emitting control transistor T5, the second light-emitting control transistor T6, and the anode reset transistor T7.

The first scan lines S include at least two of the gate reset scan line sin, the compensation scan line s2n, the bias scan line spx, and the light-emitting control scan line Emit.

For example, in one structure, the first scan lines S includes the gate reset scan line s1n, the compensation scan line s2n, the bias scan line spx and the light-emitting control scan line Emit.

In a feasible arrangement, in the “3SD structure+LTPO structure”, referring to FIG. 28, the first sub-routings 8 connected to the first gating unit 41 are located in the third source-drain metal layer sd3, the first sub-routings 8 connected to the second gating unit 42 are located in the second source-drain metal layer sd2, the second sub-routings 9 connected to the first gating unit 41 are located in the first source-drain metal layer sd1, and the second sub-routings 9 connected to the second gating unit 42 are located in the first gate metal layer m1.

The second routing S0 in the gate reset scan line sin is located in the first source-drain metal layer sd1, the second routing S0 in the compensation scan line s2n is located in the second gate metal layer mg, the second routing S0 in the light-emitting control scan line Emit is located in the first electrode metal layer mc, and the second routing S0 in the bias scan line spx is located in the first gate metal layer m1. For the gate reset scan line sin, the compensation scan line s2n, the bias scan line spx and the light-emitting control scan line Emit, the second routings S0 of at least two types of first scan lines S overlap with each other in the direction perpendicular to the plane of the substrate 20.

Or, in another feasible arrangement, in the “2SD structure+LTPO structure”, referring to FIG. 29, the first sub-routings 8 connected to the first gating unit 41 are located in the second source-drain metal layer sd2, the first sub-routings 8 connected to the second gating unit 42 are located in the first source-drain metal layer sd1, the second sub-routings 9 connected to the first gating unit 41 are located in the second gate metal layer mg, and the second sub-routings 9 connected to the second gating unit 42 are located in the first gate metal layer m1.

The second routing S0 in the compensation scan line s2n is located in the second gate metal layer mg, the second routing S0 in the light-emitting control scan line Emit is located in the first electrode metal layer mc, the second routing S0 in the bias scan line spx is located in the first gate metal layer m1, and the second routing S0 in the gate reset scan line sin is located in the shielding metal layer m0. For the gate reset scan line sin, the compensation scan line s2n, the bias scan line spx and the light-emitting control scan line Emit, the second routings S0 of at least two types of first scan lines S overlap with each other in the direction perpendicular to the plane of the substrate 20.

In addition, in this structure, the data writing scan line sp can be bilaterally driven by shift registers. Therefore, the segments in the data writing scan line sp that are disconnected at two sides of the light-transmitting hole 1 may not be connected via a routing, and the segments that are disconnected at the two sides are each connected to one shift register.

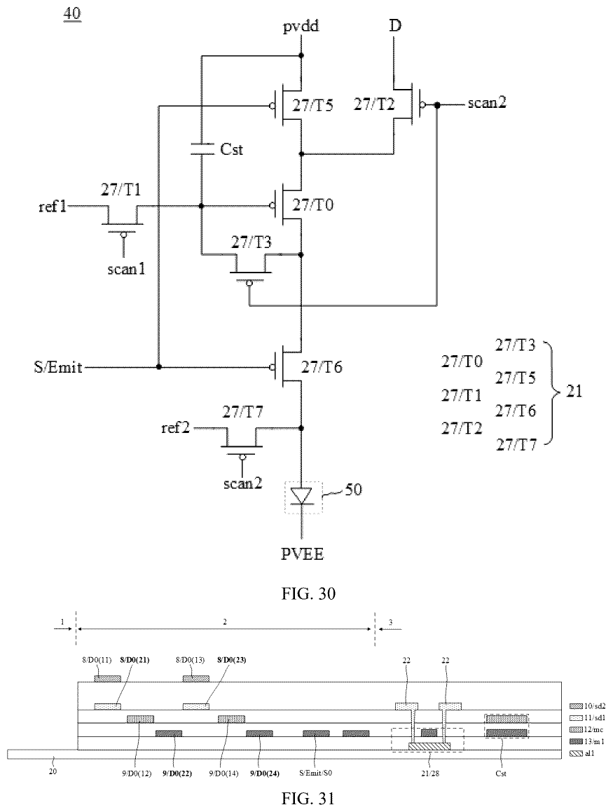

In a feasible implementation, as shown in FIG. 30 and FIG. 31, FIG. 30 is another structural schematic diagram of a pixel circuit provided by an embodiment of the present disclosure, and FIG. 31 is a schematic diagram of still another film layer position of a second routing provided by an embodiment of the present disclosure. The display panel includes a pixel circuit 40 including a plurality of transistors 21 each having an active layer including a silicon material.

The plurality of transistors 21 includes a driving transistor T0, a first light-emitting control transistor T5, and a second light-emitting control transistor T6. The first light-emitting control transistor T5 is electrically connected to a light-emitting control scan line Emit, a power line pvdd and a first electrode of the driving transistor T0 respectively, and the second light-emitting control transistor T6 is electrically connected to the light-emitting control scan line Emit, a second electrode of the driving transistor T0 and a light-emitting element 50 respectively.

The first scan lines S include the light-emitting control scan line Emit, and the second routing S0 of the light-emitting control scan line Emit and a gate of each transistor 21 are arranged in a same layer. That is, the second routing S0 of the light-emitting control scan line Emit is located in the first gate metal layer m1.

When the first scan lines S have fewer types, for example, only one type of light-emitting control scan lines Emit, the second routings S0 in the light-emitting control scan lines Emit can be arranged in the first gate metal layer m1 closer to the substrate 20. As such, a longitudinal distance between the second routings S0 and the first leads 34 can be increased, and the coupling between the two can be reduced, thereby reducing the influence of the jump of a light-emitting control scan signal on a data signal and improving display quality.

In addition, the above-mentioned pixel circuit 40 may further include a gate reset transistor T1, a data writing transistor T2, a threshold compensation transistor T3, and an anode reset transistor T7.

The gate reset transistor T1 is electrically connected to a gate reset scan line scan1, a gate reset line ref1 and a gate of the driving transistor T0 respectively.

The data writing transistor T2 is electrically connected to a data writing scan line scan2, a data line D and a first electrode of the driving transistor T0 respectively.

The threshold compensation transistor T3 is electrically connected to the data writing scan line scan2, a second electrode of the driving transistor T0 and the gate of the driving transistor T0 respectively.

The anode reset transistor T7 is electrically connected to the data writing scan line scan2, an anode reset line ref2 and a light-emitting element 50 respectively.

In addition, in this structure, a data writing scan line scan2 connected to a previous row of pixel circuits 40 and a gate reset scan line scan1 connected to a next row of pixel circuits 40 can be electrically connected to a same stage shift register, and the shift register can perform bilateral driving on the gate reset scan line scan1 and the data writing scan line scan2. The segments in the gate reset scan line scan1 and the data writing scan line scan2 that are disconnected at two sides of the light-transmitting hole 1 may not be connected via routings, and the segments that are disconnected at the two sides are each connected to one shift register.

In a feasible implementation, the display panel includes a pixel circuit 40. Taking the pixel circuit 40 shown in FIG. 27 as an example, the pixel circuit 40 includes a data writing transistor T2 electrically connected to a data writing scan line sp, one data line D and a first electrode of the driving transistor T0 respectively.

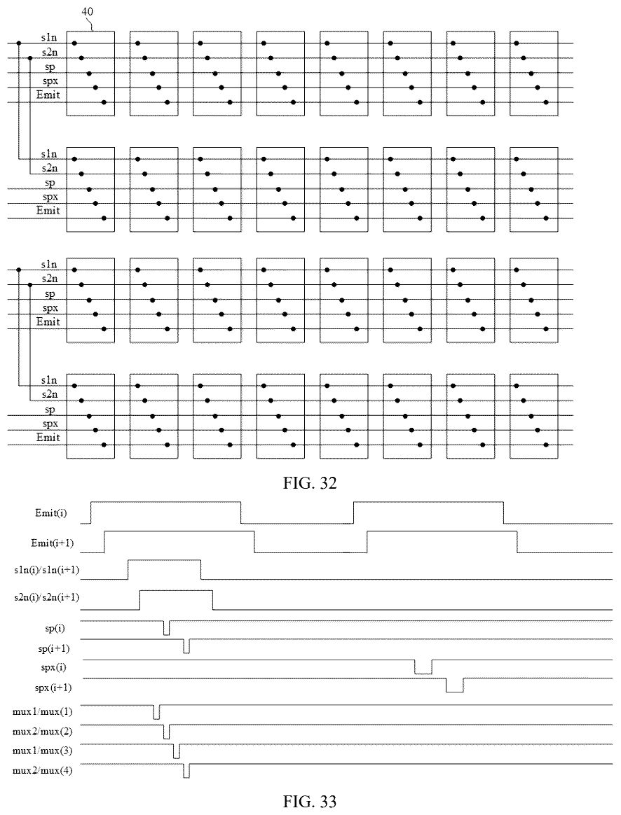

In conjunction with FIG. 3, FIG. 27, FIG. 28, FIG. 32 and FIG. 33, FIG. 32 is yet another structural schematic diagram of a display panel provided by an embodiment of the present disclosure, and FIG. 33 is a timing diagram provided by an embodiment of the present disclosure. An enable level of the first control line mux1 does not overlap with an enable level of the data writing scan line sp, and second routings S0 and first routings DO corresponding to the first control line mux 1 are arranged in different layers. An enable level of the second control line mux2 overlaps with the enable level of the data writing scan line sp, and at least some second routings S0 and at least some first routings DO corresponding to the second control line mux2 are arranged in a same layer.

For example, referring to FIG. 28, the metal layers where the second routings S0 are located are the first source-drain metal layer sd1, the first electrode metal layer mc, the first gate metal layer m1 and the shielding metal layer m0.

The first routing D0(11), the first routing D0(13), the first routing D0(21) and the first routing D0(23) corresponding to the first control lines mux 1 are located in the third source-drain metal layer sd3 and the second source-drain metal layer sd2, and this part of the first routings DO and the second routings S0 are arranged in different layers.

The first routing D0(12), the first routing D0(14), the first routing D0(22) and the first routing D0(24) corresponding to the second control lines mux2 are located in the first source-drain metal layer sd1 and the first gate metal layer m1, and this part of the first routings DO and a part of the second routings S0 are arranged in the same layers.

When the gating unit 4 performs a 1-to-4 driving design for the data lines D, one data writing scan line sp is electrically connected to two rows of pixel circuits 40.

The control line mux (1) and the control line mux (3) are the first control lines mux1, and the control line mux (2) and the control line mux (4) are the second control lines mux2.

In conjunction with FIG. 6, an i-th row of pixel circuits and an (i+1)-th row of pixel circuits are taken as an example for illustration below. In FIG. 33, the signals corresponding to the i-th row of pixel circuits are represented by their respective reference signs plus (i), and the signals corresponding to the (i+1)-th row of pixel circuits 40 are represented by their respective reference signs plus (i+1).

In the driving processes of the i-th row of pixel circuits and the (i+1)-th row of pixel circuits, referring to FIG. 33, first, the control line mux (1) provides a low level (an enable level), and the source signal line Source writes a data voltage to the data lines D corresponding to the control line mux (1). However, since a data writing scan line sp (i) corresponding to the i-th row of pixel circuits does not provide a low level during this period, the data lines D corresponding to the control line mux (1) do not charge the first pixel circuit 16 and the second pixel circuit 17 in the i-th row of pixel circuits during this period, and the data voltage is only transmitted on the data lines D.

Then, the control line mux (2) provides a low level, and at the same time, the data writing scan line sp (i) also starts to provide a low level. During this period, on one hand, the data voltage on the data lines D corresponding to the control line mux (1) start to be written into the first pixel circuit 16 and the second pixel circuit 17 in the i-th row of pixel circuits, and charges the first pixel circuit 16 and the second pixel circuit 17; and on the other hand, the data lines D corresponding to the control line mux (2) receive the data voltage provided by the source signal line Source, and at the same time synchronously writes the data voltage into the third pixel circuits 18 in the i-th row of pixel circuits.

Then, the control line mux (3) provides a low level (an enable level), and the source signal line Source writes the data voltage to the data lines D corresponding to the control line mux (3). However, since the data writing scan line sp (i+1) corresponding to the (i+1)-th row of pixel circuits does not provide a low level during this period, the data lines D corresponding to the control line mux (3) do not charge the first pixel circuit 16 and the second pixel circuit 17 in the (i+1)-th row of pixel circuits during this period, and the data voltage is only transmitted on the data lines D.

Finally, the control line mux (4) provides a low level, and at the same time, the data writing scan line sp (i+1) also starts to provide a low level. During this period, on one hand, the data voltage on the data lines D corresponding to the control line mux (4) start to be written into the first pixel circuit 16 and the second pixel circuit 17 in the (i+1)-th row of pixel circuits, and charges the first pixel circuit 16 and the second pixel circuit 17; and on the other hand, the data lines D corresponding to the control line mux (4) receive the data voltage provided by the source signal line Source, and at the same time synchronously writes the data voltage into the third pixel circuits 18 in the (i+1)-th row of pixel circuits.

From the foregoing analysis, the charging mode of the data lines D corresponding to the first control line mux 1 is only “line charging”. Before charging the pixel circuits 40, there will be a floating state for a period of time, and the signals of the data lines D are more susceptible to the influence of jumps of other signals to fluctuate, thereby affecting the charging effect. Therefore, the first routings DO in this part of data lines D and the second routings S0 can be arranged in different layers, to reduce the coupling between the two, thereby avoiding the influence of the jumps of the scan signals to a greater extent. The charging mode of the data lines D corresponding to the second control line mux2 is “line charging+direct charging”, and their charging is less affected by other signals. Considering that the first routings DO and the second routings S0 as a whole occupy a larger number of metal layers, the first routings DO in this part of data lines D and a part of the second routings S0 can be arranged in a same layer, so that the number of original metal layers in the display panel meets the wiring requirement of the routings.

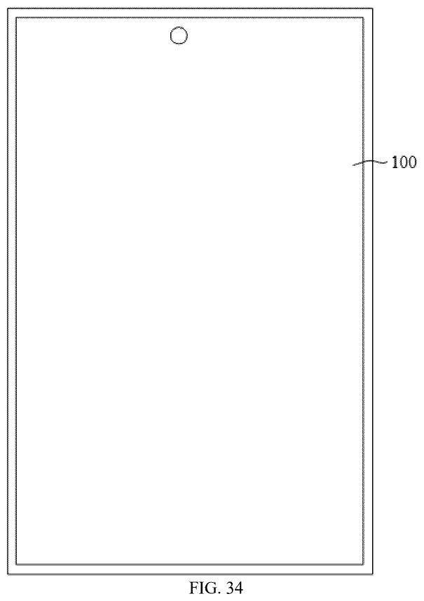

Based on the same inventive concept, an embodiment of the present disclosure further provides a display apparatus. As shown in FIG. 34, which is a structural schematic diagram of a display apparatus provided by an embodiment of the present disclosure, the display apparatus includes the above-mentioned display panel 100. Of course, the display apparatus shown in FIG. 34 is merely illustrative, and the display apparatus may be any electronic device having a display function, such as a mobile phone, a tablet computer, a notebook computer, an e-book or a television.

The above-described are only the preferred embodiments of the present disclosure and are not intended to limit the present disclosure. Any modification, equivalent substitution, improvement, etc., made within the spirit and principle of the present disclosure shall be included in the protection scope of the present disclosure.

Finally, it should be explained that: the above various embodiments are only used to illustrate the technical solutions of the present disclosure, rather than to limit them; although the present disclosure has been described in detail with reference to the foregoing various embodiments, those of skill in the art should understand that they can still modify the technical solutions recited in the foregoing various embodiments, or perform equivalent substitutions on some or all of the technical features therein; and these modifications or substitutions do not cause the essence of the corresponding technical solutions to deviate from the scope of the technical solutions of the various embodiments of the present disclosure.

What is claimed is:

1. A display panel, comprising:
a light-transmitting hole;
a first non-display region surrounding the light-transmitting hole;
a display region surrounding the first non-display region;
data lines, a part of the data lines comprising a first segment, a first routing and a second segment, wherein the first segment and the second segment are disconnected at two sides of the light-transmitting hole and at least located in the display region, and the first routing is connected between the first segment and the second segment and located in the first non-display region; and
a plurality of gating units, each gating unit comprising at least two gating switches, wherein in the gating unit, input terminals of the at least two gating switches are electrically connected to one source signal line, control terminals of the at least two gating switches are electrically connected to at least two control lines respectively, and output terminals of the at least two gating switches are electrically connected to at least two data lines respectively;
wherein the first routing corresponding to a control line is the first routing connected to a gating switch connected to the control line;
the at least two control lines comprise at least one first control line and at least one second control line; and
the plurality of gating units comprise a first gating unit and a second gating unit; and for the first routings connected to the first gating unit and the second gating unit: the first routings corresponding to a same first control line are arranged in different layers, and at least partially overlap with each other in a direction perpendicular to a plane of the display panel; and the first routings corresponding to the at least one first control line and the first routings corresponding to the at least one second control line are arranged in different layers, and the first routings corresponding to the at least one first control line at least partially do not overlap with the first routings corresponding to the at least one second control line in the direction perpendicular to the plane of the display panel.

2. The display panel according to claim 1, further comprising:
first data line groups and second data line groups that are arranged alternately, the first data line groups and the second data line groups respectively comprising at least two adjacent data lines;
wherein the first gating unit is electrically connected to a first data line group, and the second gating unit is electrically connected to a second data line group.

3. The display panel according to claim 1, wherein
the plurality of gating units each comprise 2m gating switches, and the at least two control lines comprise m first control lines and m second control lines, where m≥1;
the first routing comprises a first sub-routing corresponding to one first control line and a second sub-routing corresponding to one second control line;
first sub-routings electrically connected to the first gating unit are located in a first metal layer, first sub-routings electrically connected to the second gating unit are located in a second metal layer, second sub-routings electrically connected to the first gating unit are located in a third metal layer, and second sub-routings electrically connected to the second gating unit are located in a fourth metal layer; and
for the first routings connected to a same gating unit, orthographic projections of two adjacent first sub-routings on the plane of the display panel are spaced by an orthographic projection of one second sub-routing on the plane of the display panel, and orthographic projections of two adjacent second sub-routings on the plane of the display panel are spaced by an orthographic projection of one first sub-routing on the plane of the display panel.

4. The display panel according to claim 3, wherein
m=2.

5. The display panel according to claim 1, wherein
the first routing comprises a first sub-routing corresponding to one first control line;
first sub-routings electrically connected to the first gating unit are located in a first metal layer, and first sub-routings electrically connected to the second gating unit are located in a second metal layer; and
the first metal layer and the second metal layer are spaced by a planarization layer.

6. The display panel according to claim 5, further comprising:
a substrate, a transistor and connection electrodes, wherein the connection electrodes are electrically connected to a doped region of an active layer in the transistor through via holes;
wherein the planarization layer comprises a first planarization layer and a second planarization layer, the first planarization layer is located on one side of the connection electrodes away from the substrate, and the second planarization layer is located on one side of the first planarization layer away from the substrate; and
wherein the first metal layer is located on one side of the second planarization layer away from the substrate, and the second metal layer is located between the first planarization layer and the second planarization layer.

7. The display panel according to claim 5, further comprising:
a substrate, a transistor and connection electrodes, wherein the connection electrodes are electrically connected to a doped region of an active layer in the transistor through via holes;
wherein the planarization layer comprises a first planarization layer located on one side of the connection electrodes away from the substrate; and
wherein the first metal layer is located on one side of the first planarization layer away from the substrate, and the second metal layer comprises the connection electrodes.

8. The display panel according to claim 1, wherein
the first routing comprises a second sub-routing corresponding to one second control line;
second sub-routings electrically connected to the first gating unit are located in a third metal layer, and second sub-routings electrically connected to the second gating unit are located in a fourth metal layer; and
the third metal layer and the fourth metal layer are spaced by an inorganic insulating layer.

9. The display panel according to claim 8, wherein
the third metal layer and the fourth metal layer are spaced by other metal layers; and
for the second sub-routings connected to the first gating unit and the second gating unit, the second sub-routings corresponding to a same second control line at least partially overlap with each other in the direction perpendicular to the plane of the display panel.

10. The display panel according to claim 9, further comprising:
a substrate, a transistor and connection electrodes, wherein the connection electrodes are electrically connected to a doped region of an active layer in the transistor through via holes; and
wherein the third metal layer comprises the connection electrodes, and the fourth metal layer is located on one side of the third metal layer close to the substrate.

11. The display panel according to claim 9, further comprising:
a substrate and a transistor, wherein the transistor comprises a first transistor, and an active layer of the first transistor comprises a metal oxide material; and
wherein the third metal layer comprises a gate of the first transistor, and the fourth metal layer is located on one side of the third metal layer close to the substrate.

12. The display panel according to claim 10, wherein
the transistor comprises a second transistor, an active layer of the second transistor comprises a silicon material, and the fourth metal layer comprises a gate of the second transistor; or
the display panel further comprises a shielding metal located between the transistor and the substrate, the shielding metal overlaps with a channel of the transistor in a direction perpendicular to a plane of the substrate, and the fourth metal layer comprises the shielding metal.

13. The display panel according to claim 8, wherein
the third metal layer and the fourth metal layer are two adjacent metal layers; and
for the second sub-routings connected to the first gating unit and the second gating unit, the second sub-routings corresponding to a same second control line at least partially do not overlap with each other in the direction perpendicular to the plane of the display panel.

14. The display panel according to claim 13, further comprising:
a substrate, a storage capacitor and a transistor, wherein the transistor comprises a second transistor, and an active layer of the second transistor comprises a silicon material,
wherein the third metal layer comprises a first plate of the storage capacitor, and the fourth metal layer comprises a gate of the second transistor and a second plate of the storage capacitor.

15. The display panel according to claim 1, wherein
the each gating unit comprises three gating switches, the control lines comprise n first control lines and 3-n second control lines, where n=1 or n=2;
wherein for first routings corresponding to a first control line, the first routings electrically connected to the first gating unit and the second gating unit are located in a first metal layer and a second metal layer respectively;
wherein for first routings corresponding to a second control line, the first routings electrically connected to the first gating unit and the second gating unit are located in a third metal layer and a fourth metal layer respectively; and
wherein for first routings corresponding to a third control line, the first routings electrically connected to the first gating unit and the second gating unit are located in a fifth metal layer and a sixth metal layer respectively.

16. The display panel according to claim 15, wherein
n=2;
the display panel further comprises a substrate, and distances between the first metal layer, the second metal layer, the third metal layer, the fourth metal layer, the fifth metal layer, and the sixth metal layer and the substrate decrease gradually; and
for the first routings electrically connected to the first gating unit and the second gating unit, the first routings corresponding to one control line are located in the first metal layer and the second metal layer respectively, the first routings corresponding to the other first control line are located in the fifth metal layer and the sixth metal layer respectively, and the first routings corresponding to two first control lines at least partially overlap with each other in the direction perpendicular to the plane of the display panel.

17. The display panel according to claim 1, further comprising:
first scan lines, a part of the first scan lines each comprising a third segment, a second routing, and a fourth segment, wherein the third segment and the fourth segment are disconnected at two sides of the light-transmitting hole and at least located in the display region, an extension direction of the third segment and the fourth segment intersects with an extension direction of the first segment and the second segment, and the second routing is connected between the third segment and the fourth segment and located in the first non-display region; and
the second routing is located on one side of the first routing away from the light-transmitting hole.

18. The display panel according to claim 17, wherein
the first routing and the first segment as well as the first routing and the second segment are connected via first leads respectively; and
in a plane perpendicular to the display panel, the first leads overlap with the second routing, and the first leads extend in a same direction as the first segment and the second segment.

19. The display panel according to claim 18, wherein
the first leads are arranged in a same layer as the first segment and the second segment; and/or
the display panel further comprises a substrate, a transistor and connection electrodes, wherein the connection electrodes are electrically connected to a doped region of an active layer in the transistor through via holes, and a metal layer where the first leads are located is arranged on one side of a metal layer where the connection electrodes are located away from the substrate.

20. The display panel according to claim 18, wherein
the first leads comprises a first sub-lead and a second sub-lead; and
wherein the first sub-lead and the first routing connected thereto are arranged in different layers and are connected to each other through a first connection portion, the second sub-lead and the first routing connected thereto are arranged in a same layer and are connected to each other through a second connection portion, and the first connection portion and the second connection portion are arranged in a same layer.

21. The display panel according to claim 18, wherein
at least some first leads and first routings connected thereto are arranged in different layers and are connected through connection portions, and the connection portions are located between the first routings and second routings.

22. The display panel according to claim 17, further comprising:
at least two types of first scan lines, second routings of a same type of first scan lines are arranged in a same layer, second routings of different types of first scan lines are arranged in different layers, and in the direction perpendicular to the plane of the display panel, there is at least an overlap between second routings of two types of first scan lines.

23. The display panel according to claim 22, further comprising:
a pixel circuit comprising a storage capacitor and a plurality of transistors, wherein the plurality of transistors comprise a first transistor and a second transistor, an active layer of the first transistor comprises a metal oxide material, and an active layer of the second transistor comprises a silicon material;
connection electrodes electrically connected to a doped region of an active layer in each transistor through via holes, and second routings of one type of first scan lines is arranged in a same layer as the connection electrodes; and/or
second routings of another type of first scan lines and a gate of the first transistor are arranged in a same layer; and/or
second routings of still another type of first scan lines and a first plate of the storage capacitor are arranged in a same layer; and/or
second routings of yet another type of first scan lines are arranged in a same layer as a gate of the second transistor and a second plate of the storage capacitor; and/or
a substrate and a shielding metal, wherein the shielding metal is located between the second transistor and the substrate, the shielding metal overlaps with a channel of the second transistor in a direction perpendicular to a plane of the substrate, and the second routings of a further type of first scan lines are arranged in a same layer as the shielding metal.

24. The display panel according to claim 23, wherein the plurality of transistors comprise:
a driving transistor;
a gate reset transistor electrically connected to a gate reset scan line, a gate reset line and a gate of the driving transistor respectively;
a data writing transistor electrically connected to a data writing scan line, one data line and a first electrode of the driving transistor respectively;
a threshold compensation transistor electrically connected to a compensation scan line, a second electrode of the driving transistor and the gate of the driving transistor respectively;
a bias transistor electrically connected to a bias scan line, a bias signal line and the driving transistor respectively;
a first light-emitting control transistor electrically connected to a light-emitting control scan line, a power line and the first electrode of the driving transistor respectively; and
a second light-emitting control transistor electrically connected to the light-emitting control scan line, the second electrode of the driving transistor and a light-emitting element respectively;
wherein the first transistor comprises at least one of the gate reset transistor and the threshold compensation transistor, and the second transistor comprises at least one of the driving transistor, the data writing transistor, the first light-emitting control transistor, and the second light-emitting control transistor; and
wherein the first scan lines comprise at least two of the gate reset scan line, the compensation scan line, the bias scan line, and the light-emitting control scan line.

25. The display panel according to claim 17, further comprising:
a pixel circuit comprising a plurality of transistors each having an active layer comprising a silicon material;
wherein the plurality of transistors comprise a driving transistor, a first light-emitting control transistor and a second light-emitting control transistor, the first light-emitting control transistor is electrically connected to a light-emitting control scan line, a power line and a first electrode of the driving transistor respectively, and the second light-emitting control transistor is electrically connected to the light-emitting control scan line, a second electrode of the driving transistor and a light-emitting element respectively; and
wherein the first scan lines comprises the light-emitting control scan line, and second routing of the light-emitting control scan line is arranged in a same layer as a gate of each transistor.

26. The display panel according to claim 17, further comprising:
a pixel circuit comprising a driving transistor and a data writing transistor, wherein the data writing transistor is electrically connected to a data writing scan line, one data line and a first electrode of the driving transistor;
wherein an enable level of the first control line does not overlap with an enable level of the data writing scan line, and second routings and first routings corresponding to the first control line are arranged in different layers; and
an enable level of the second control line overlaps with the enable level of the data writing scan line, and at least some second routings and at least some first routings corresponding to the second control line are arranged in a same layer.

27. A display apparatus, comprising a display panel, wherein the display panel comprising:
a light-transmitting hole;
a first non-display region surrounding the light-transmitting hole;
a display region surrounding the first non-display region;
data lines, a part of the data lines comprising a first segment, a first routing and a second segment, wherein the first segment and the second segment are disconnected at two sides of the light-transmitting hole and at least located in the display region, and the first routing is connected between the first segment and the second segment and located in the first non-display region; and
a plurality of gating units, each gating unit comprising at least two gating switches, wherein in the gating unit, input terminals of the at least two gating switches are electrically connected to one source signal line, control terminals of the at least two gating switches are electrically connected to at least two control lines respectively, and output terminals of the at least two gating switches are electrically connected to at least two data lines respectively;
wherein the first routing corresponding to a control line is the first routing connected to a gating switch connected to the control line;
the at least two control lines comprise at least one first control line and at least one second control line; and
the plurality of gating units comprise a first gating unit and a second gating unit; and for the first routings connected to the first gating unit and the second gating unit: the first routings corresponding to a same first control line are arranged in different layers, and at least partially overlap with each other in a direction perpendicular to a plane of the display panel; and the first routings corresponding to the at least one first control line and the first routings corresponding to the at least one second control line are arranged in different layers, and the first routings corresponding to the at least one first control line at least partially do not overlap with the first routings corresponding to the at least one second control line in the direction perpendicular to the plane of the display panel.
